(19) United States
(12) Patent Application Publication
(10) Pub. No.: US 2025/0293123 A1
(43) Pub. Date: Sep. 18, 2025

(54) SEMICONDUCTOR DEVICE AND METHOD FOR MANUFACTURING THE SAME

(71) Applicant: Rohm Co., Ltd., Kyoto-shi (JP)

(72) Inventor: Hiroyuki SHINKAI, Kyoto-shi (JP)

(21) Appl. No.: 19/077,696

(22) Filed: Mar. 12, 2025

(30) Foreign Application Priority Data
Mar. 15, 2024 (JP) 2024-040754
Mar. 22, 2024 (JP) 2024-046305

(51) Int. Cl. H01L 23/495; H01L 23/00; H01L 23/31

(52) U.S. Cl. CPC H01L 23/49503; H01L 23/3107; H01L 23/49548; H01L 24/16; H01L 24/48; H01L 2224/16245; H01L 2224/48247

(57) ABSTRACT

A semiconductor device includes a semiconductor element with an element main surface facing in a thickness direction and being provided with an electrode, and a sealing resin including a resin top surface facing a first side of the thickness direction. The sealing resin covers the semiconductor element. The element main surface and the resin top surface are rectangular. The first edge of the element main surface is inclined with respect to the second edge of the resin top surface, as viewed in the thickness direction.

### FIELD

The present disclosure relates to a semiconductor device and a method for manufacturing semiconductor devices.

### BACKGROUND

Various configurations of semiconductor devices with semiconductor elements incorporated have been proposed. JP-A-2023-42910 discloses an example of an electronic device whose package type is QFN (Quad Flat Non-Lead Package). The electronic device disclosed in this document has a plurality of leads, electronic components, and resin members. The electronic components are supported by the plurality of leads. The resin member covers a portion of each lead and the electronic component. The resin member and the electronic component are rectangular in plan view. In the electronic device, the end faces of the plurality of leads are exposed so that they are flush with the sides of the resin member. In addition, the back surfaces of the plurality of leads are exposed so that they are flush with the back surface of the resin member. Therefore, compared to a QFP (Quad Flat Package) in which the leads protrude from the sides of the resin member, this electronic device has the advantage that it can be downsized and the mounting area on the circuit board can be reduced. On the other hand, this electronic device has lower mounting reliability than the QFP.

When semiconductor devices (in JP-A-2023-42910, referred to as electronic devices) are mounted on a circuit board with solder or other means, the lead located at each corner is subject to stress concentration of the difference in linear expansion coefficient at the solder to be bonded to the back surface. Therefore, compared to other leads, mounting reliability is lower for these leads. In addition, as the chip occupancy ratio becomes larger, which is the ratio of the area of the semiconductor element to the area of the semiconductor device in plan view, the mounting reliability becomes lower. This is because the larger the chip occupancy ratio, the shorter the distance between the corners of the semiconductor device and the semiconductor element.

### BRIEF DESCRIPTION OF THE DRAWINGS

FIG. 1 is a diagram showing a semiconductor device in accordance with a first embodiment of the present disclosure.

FIG. 2 is a plan view showing the semiconductor device in accordance with the first embodiment of the present disclosure.

FIG. 3 is a plan view showing the semiconductor device in accordance with the first embodiment of the present disclosure (with the sealing resin being transparent).

FIG. 4 is a bottom view showing the semiconductor device according to the first embodiment of the present disclosure.

FIG. 5 is a front view showing the semiconductor device in accordance with the first embodiment of the present disclosure.

FIG. 6 is a rear view showing the semiconductor device according to the first embodiment of the present disclosure.

FIG. 7 is a right side view showing the semiconductor device according to the first embodiment of the present disclosure.

FIG. 8 is a left side view showing the semiconductor device according to the first embodiment of the present disclosure.

FIG. 9 is a cross-sectional view along the IX-IX line of FIG. 3.

FIG. 10 is a cross-sectional view along the X-X line of FIG. 3.

FIG. 11 is a cross-sectional view along the XI-XI line of FIG. 3.

FIG. 12 is a cross-sectional view along the XII-XII line of FIG. 3.

FIG. 13 is a cross-sectional view along the XIII-XIII line of FIG. 3.

FIG. 14 is a plan view of a semiconductor device according to a first variation of the first embodiment.

FIG. 15 is a plan view showing a semiconductor device according to a second embodiment of the present disclosure (with the sealing resin being transparent).

FIG. 16 is a cross-sectional view along the XVI-XVI line of FIG. 15.

FIG. 17 is a plan view (with the sealing resin being transparent) showing a semiconductor device according to a first variation of the second embodiment.

FIG. 18 is a plan view (with the sealing resin being transparent) showing a semiconductor device according to a second variation of the second embodiment.

FIG. 19 is a plan view (with the sealing resin being transparent) showing a semiconductor device in accordance with a third embodiment of the present disclosure.

FIG. 20 is a plan view showing a semiconductor device in accordance with a fourth embodiment of the present disclosure.

FIG. 21 is a cross-sectional view along the XXI-XXI line of FIG. 20.

FIG. 22 is a diagrammatic view showing a semiconductor device in accordance with a fifth embodiment of the present disclosure.

FIG. 23 is a plan view (with the sealing resin being transparent) showing the semiconductor device according to the fifth embodiment of the present disclosure.

FIG. 24 is a plan view (with the sealing resin and the semiconductor element being transparent) showing the semiconductor device in accordance with the fifth embodiment of the present disclosure.

FIG. 25 is a bottom view showing the semiconductor device according to the fifth embodiment of the present disclosure.

FIG. 26 is a front view showing the semiconductor device in accordance with the fifth embodiment of the present disclosure.

FIG. 27 is a rear view showing the semiconductor device in accordance with the fifth embodiment of the present disclosure.

FIG. 28 is a right side view showing the semiconductor device in accordance with the fifth embodiment of the present disclosure.

FIG. 29 is a left side view showing the semiconductor device in accordance with the fifth embodiment of the present disclosure.

FIG. 30 is a cross-sectional view along the XXX-XXX line of FIG. 24.

FIG. 31 is a cross-sectional view along the XXXI-XXXI line of FIG. 24.

FIG. 32 is a cross-sectional view along the XXXII-XXXII line of FIG. 24.

FIG. 33 is a cross-sectional view along the XXXIII-XXXIII line of FIG. 24.

FIG. 34 is a cross-sectional view along the XXXIV-XXXIV line of FIG. 24.

FIG. 35 is a partially enlarged diagram showing the semiconductor device according to the fifth embodiment of the present disclosure.

FIG. 36 is a bottom view showing a process for manufacturing the semiconductor device in accordance with the fifth embodiment of the present disclosure.

FIG. 37 is a cross-sectional view along the XXXVII-XXXVII line of FIG. 36.

FIG. 38 is a bottom view illustrating a process for manufacturing the semiconductor device pertaining to the fifth embodiment of the present disclosure.

FIG. 39 is a cross-sectional view along the XXXIX-XXXIX line of FIG. 38.

FIG. 40 is a bottom view showing a semiconductor device in accordance with a first variation of the fifth embodiment.

FIG. 41 is a partially enlarged diagram showing the semiconductor device according to the first variation of the fifth embodiment.

FIG. 42 is a bottom view showing a semiconductor device according to a second variation of the fifth embodiment.

FIG. 43 is a partially enlarged diagram showing the semiconductor device according to the second variant of the fifth embodiment.

FIG. 44 is a front view showing a semiconductor device according to a third variation of the fifth embodiment.

FIG. 45 is a plan view showing a semiconductor device according to a sixth embodiment of the present disclosure (with the sealing resin being transparent).

FIG. 46 is a bottom view showing the semiconductor device according to the sixth embodiment of the present disclosure.

FIG. 47 is a cross-sectional view along the XLVII-XLVII line of FIG. 45.

FIG. 48 is a plan view (with the sealing resin being transparent) showing a semiconductor device according to a first variation of the sixth embodiment.

### DETAILED DESCRIPTION OF EMBODIMENTS

Embodiments according to the present disclosure will be described below with reference to the accompanying drawings.

The terms “first,” “second,” “third,” etc., in this disclosure are used simply as labels and are not necessarily intended to denote the order of those objects.

Unless otherwise noted, the phrases such as “an object A is formed in an object B” and “an object A is formed on an object B” used in the present disclosure include “the object A is formed in direct contact with the object B” and “the object A is formed on the object B with another object interposed between the object A and the object B”. Similarly, unless otherwise noted, the phrases such as “an object A is arranged in an object B” and “an object A is arranged on an object B” include “the object A is arranged with direct contact with the object B” and “the object A is arranged on the object B with another object interposed between the object A and the object B”. Similarly, unless otherwise noted, the phrase reading “an object A is located on an object B” include “the object A is located in direct contact with the object B” and “the object A is located on the object B with another object interposed between the object A and the object B”. Additionally, unless otherwise noted, the phrase “an object A overlaps with an object B as viewed in a certain direction” includes “the object A overlaps with the entire object B as viewed in the direction” and “the object A overlaps with a portion of the object B as viewed in the direction”. Additionally, unless otherwise noted, the phrase “a surface A faces (one side or another side of) a direction B” includes a case where the surface A is inclined with respect to the direction B, so that the direction B is not orthogonal to the surface A.

### First Embodiment

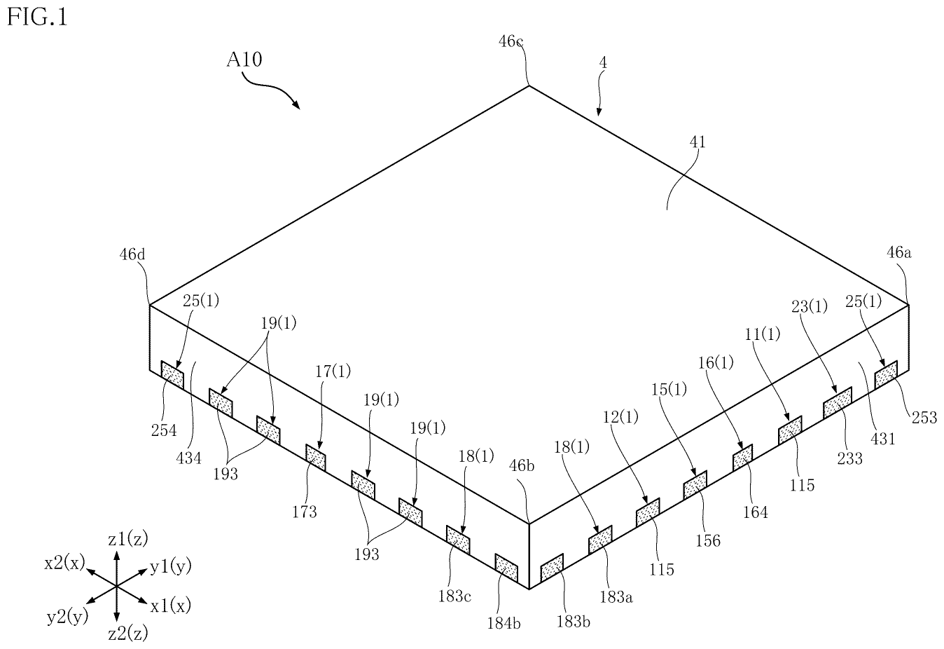

Based on FIGS. 1 to 13, a semiconductor device A10 according to the first embodiment of the present disclosure will be described. The semiconductor device A10 in this embodiment has a conductive member 1, a semiconductor element 3, and a sealing resin 4. As shown in FIG. 1, the package type of the semiconductor device A10 is a QFN (Quad For Non-Lead Package). The configurations of the semiconductor element 3 are not particularly limited. In this embodiment, the semiconductor element 3 is, for example, a flip chip type LSI (Large Scale Integration) in which a switching circuit and a control circuit (details of each are described below) are incorporated. In semiconductor device A10, DC power (voltage) is converted to AC power (voltage) by the switching circuit. The semiconductor device A10 is used, for example, as an element that constitutes the circuit of a DC/DC converter. The functions and uses of the semiconductor device A10 are not limited.

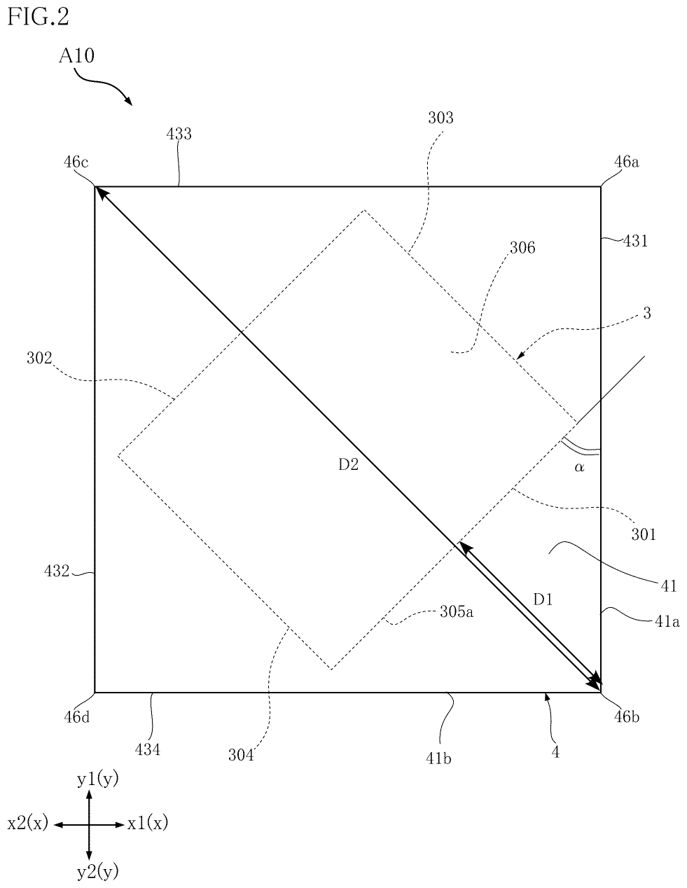

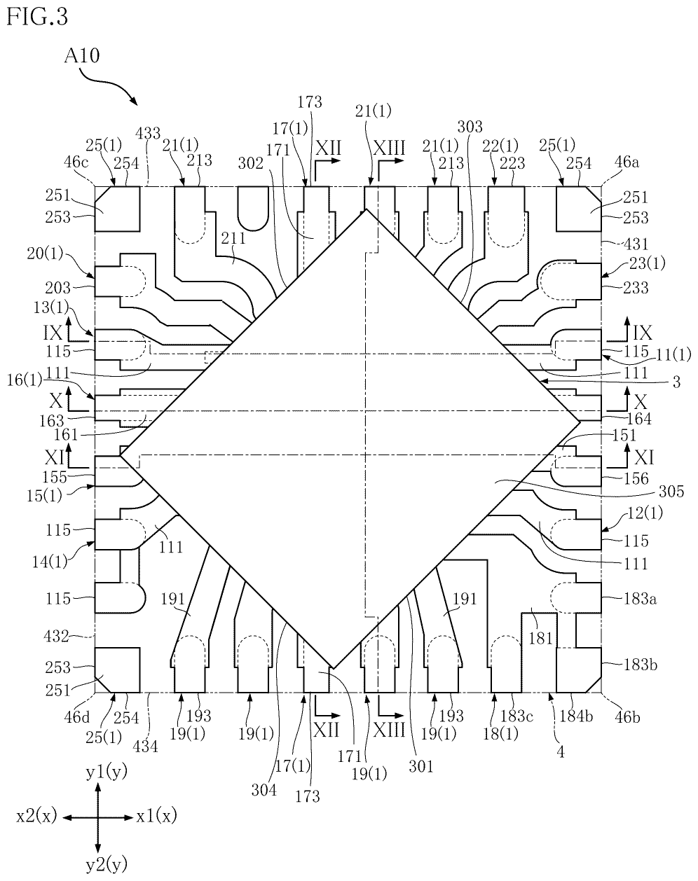

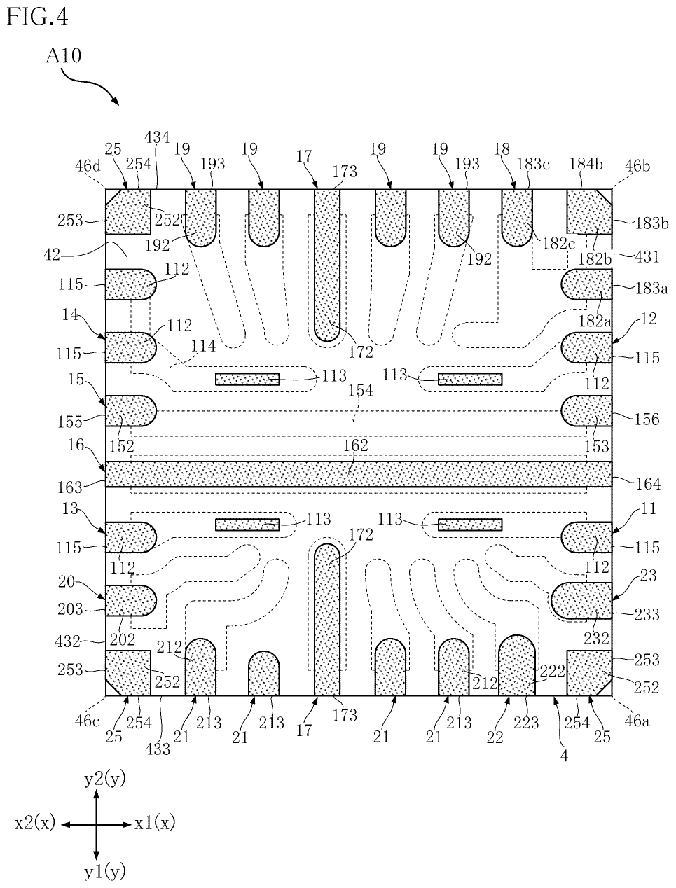

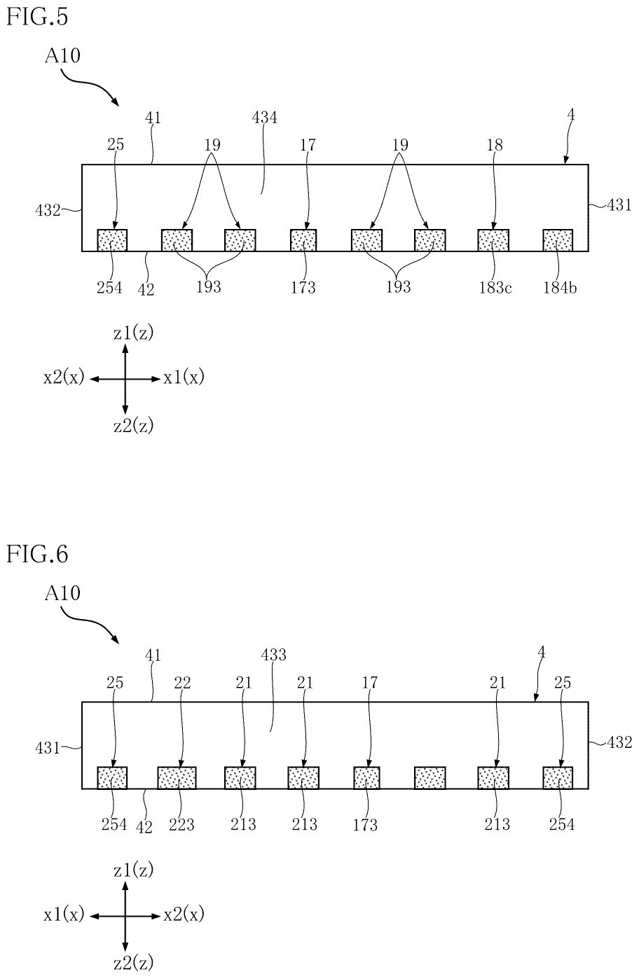

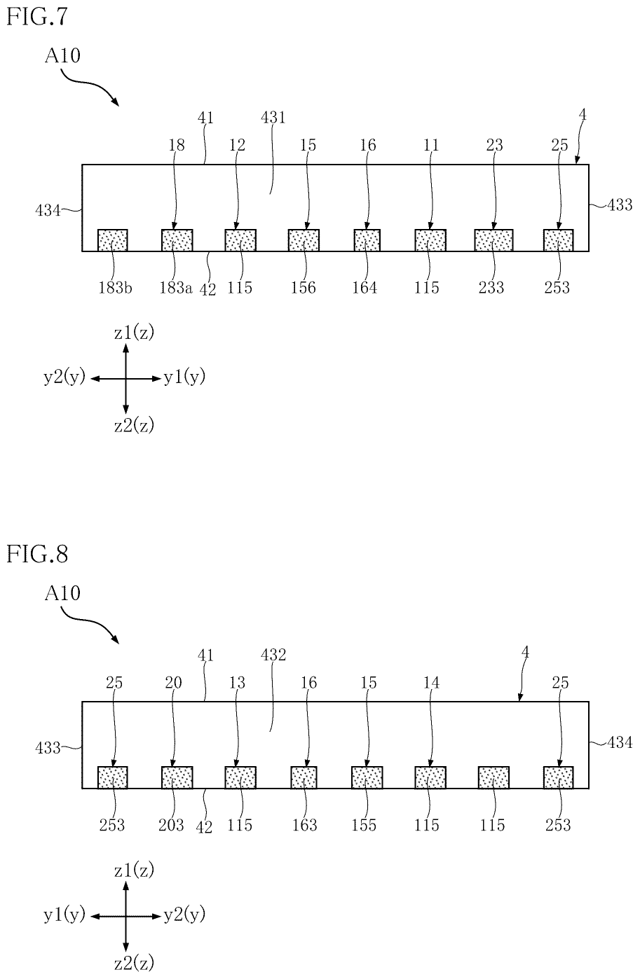

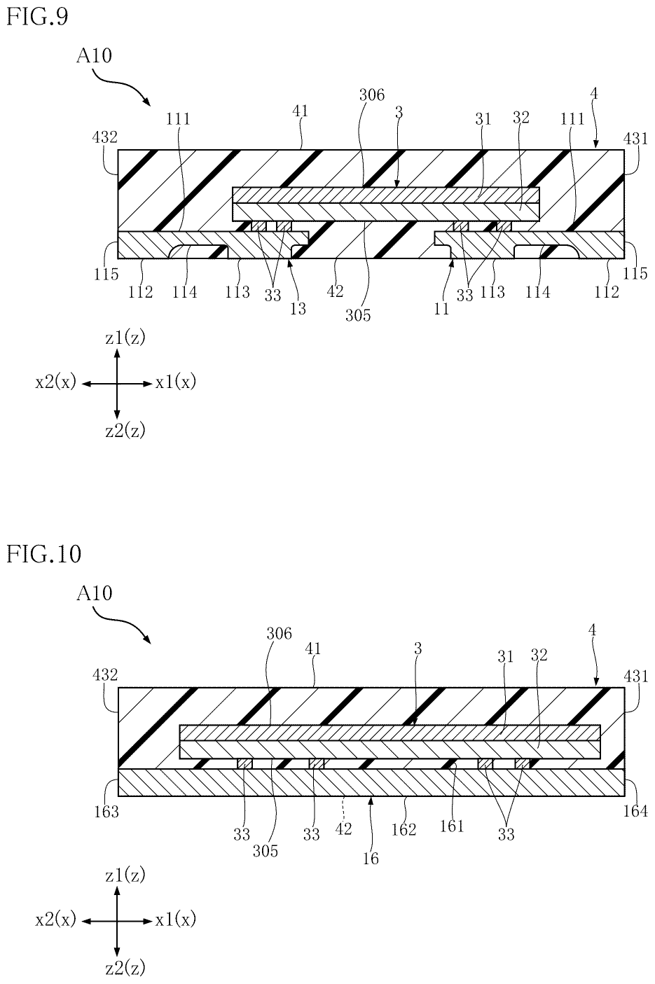

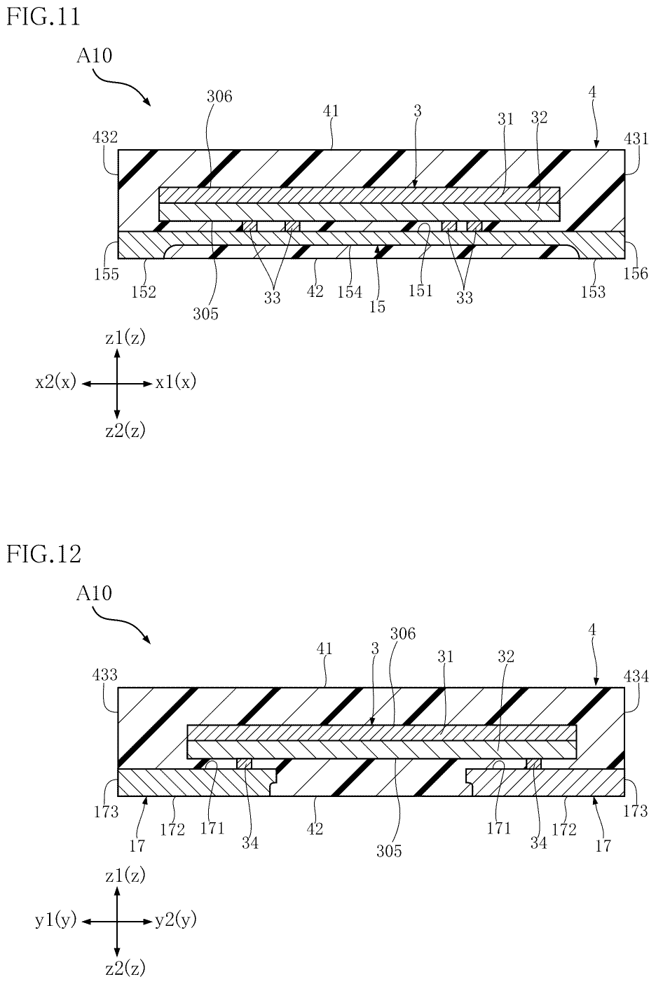

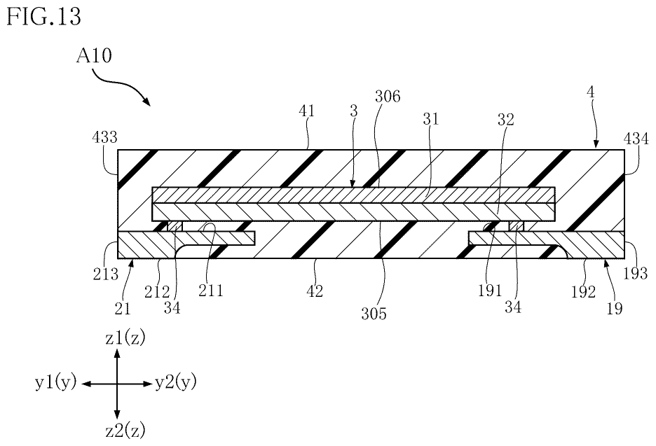

FIG. 1 is a diagram showing the semiconductor device A10. FIG. 2 is a plan view showing the semiconductor device A10. FIG. 3 is a plan view showing the semiconductor device A10. FIG. 4 is a bottom view showing the semiconductor device A10. FIG. 5 is a front view showing the semiconductor device A10. FIG. 6 is a rear view showing the semiconductor device A10. FIG. 7 is a right side view showing the semiconductor device A10. FIG. 8 is a left side view showing the semiconductor device A10. FIG. 9 is a cross-sectional view along the IX-IX line of FIG. 3. FIG. 10 is a cross-sectional view along the X-X line of FIG. 3. FIG. 11 is a cross-sectional view along the XI-XI line of FIG. 3. FIG. 12 is a cross-sectional view along the XII-XII line of FIG. 3. FIG. 13 is a cross-sectional view along the XIII-XIII line of FIG. 3. In FIG. 3, the sealing resin 4 is made transparent for convenience of understanding.

The semiconductor device A10 is rectangular in shape as viewed in the thickness direction (in planar view). For convenience of description, the normal direction extending through the thickness of the semiconductor device A10 is the thickness direction z. The direction perpendicular to the thickness direction z and extending along one side of the semiconductor device A10 (left and right directions in FIGS. 2 and 3) is the first direction x. The direction perpendicular to the thickness direction z and the first direction x (vertical direction in FIGS. 2 and 3) is the second direction y. The dimensions (sizes) of the semiconductor device A10 are not limited.

As shown in FIG. 2, the conductive member 1 includes a plurality of leads 11-14, a lead 15, a lead 16, a pair of leads 17, a lead 18, a plurality of leads 19, a lead 20, a plurality of leads 21, a lead 22, a lead 23 and a plurality of leads 25. The conductive member 1 supports the semiconductor element 3 and serves as a terminal for mounting the semiconductor device A10 on a circuit board. The above-mentioned leads 11-25 are provided by the same lead frame. The material used to construct the lead frame contains, for example, copper or copper alloy. As shown in FIGS. 3 to 4 and FIGS. 9 to 13, the leads 11 to 23 and 25 are partially covered with the sealing resin 4.

The leads 11-14 are arranged on the first side x1 of the first direction x or on the second side x2 of the first direction x in the semiconductor device A10, as shown in FIGS. 3 and 4. In this embodiment, two leads 11, 12 are disposed on the first side x1 of the first direction x, and the other two leads 13, 14 are disposed on the second side x2 of the first direction x. In this embodiment, the plurality of leads 11-14 each extend generally in the first direction x. The pair of leads 11, 12 are spaced apart in the second direction y, and the pair of leads 13, 14 are spaced apart in the second direction y. Each of the leads 11-14 outputs AC power (voltage) that is converted by the switching circuit that includes the semiconductor element 3.

As shown in FIGS. 3, 4, and 9, each of the leads 11-14 has a main surface 111, a back surface 112, a back surface 113, a concave surface 114, and an end surface 115. The main surface 111 faces the first side z1 of the thickness direction z and faces the semiconductor element 3. The main surface 111 is covered by the sealing resin 4. The semiconductor element 3 is supported by the main surface 111.

The back surfaces 112, 113 and the concave surface 114 face away from the main surface 111 (in the second side z2 of the thickness direction z). The back surfaces 112, 113 are located apart from each other across the concave surface 114 in the first direction x and are exposed from the sealing resin 4. The concave surface 114 is closer to the first side z1 in the thickness direction z than the back surfaces 112, 113 and therefore closer to the main surface 111 than the back surfaces 112, 113. The concave surface 114 is covered by the sealing resin 4. The end surface 115 is connected to the main surface 111 and the back surface 112 and faces the first side x1 of the first direction x or the second side x2 of the first direction x. The end faces 115 are exposed from the sealing resin 4. As shown in FIG. 4, the lead 14 has two back surfaces 112 and two end surfaces 115. One pair of the back surface 112 and the end surface 115 is separated from the other pair of the back surface 112 and the end surface 115 in the second direction y.

In each of the leads 11-14, the main surface 111 supporting the semiconductor element 3 may be silver plated, for example. The back surfaces 112, 113 and the end surfaces 115 exposed from the sealing resin 4 may be tin plated, for example. Instead of the tin plating, a plurality of metal plating may be employed, for example, nickel, palladium and gold layered in this order.

The lead 15 extends in the first direction x, as shown in FIGS. 3 and 4. In this embodiment, the lead 15 is located in the middle of the semiconductor device A10 in the second direction y. The lead 15 is an input terminal where the DC power (voltage) to be converted in the semiconductor device A10 is inputted. The lead 15 is a positive terminal.

As shown in FIG. 11, the lead 15 has a main surface 151, back surfaces 152, 153, a concave surface 154 and end surfaces 155, 156. The main surface 151 faces the same side as the main surfaces 111 of the leads 11-14 in the thickness direction z and faces the semiconductor element 3. The main surface 151 is covered by the sealing resin 4. The semiconductor element 3 is supported by the main surface 151.

The back surfaces 152, 153 and the concave surface 154 face away from the main surface 151 (in the second side z2 of the thickness direction z). The back surfaces 152, 153 are located apart from each other across the concave surface 154 in the first direction x and are exposed from the sealing resin 4. The back surface 152 is located on the second side x2 of the first direction x and the back surface 153 is located on the first side x1 of the first direction x. The concave surface 154 is located closer to the first side z1 of the thickness direction z than the back surface 152 and the back surface 153 and is closer to the main surface 151 than the back surface 152, 153. The concave surface 154 is covered by the sealing resin 4. The end surface 155 is connected to the main surface 151 and the back surface 152 and faces the second side x2 of the first direction x.

The end surface 156 is connected to the main surface 151 and the back surface 153 and faces the first side x1 of the first direction x. The end surfaces 155, 156 are exposed from the sealing resin 4.

In the lead 15, the main surface 151 on which semiconductor element 3 is supported may be silver plated, for example. In addition, the back surfaces 152, and the end surfaces 155, 156 exposed from the sealing resin 4 may be tin plated, for example. Instead of the tin plating, a plurality of metal plating may be employed, for example, nickel, palladium, and gold layered in that order.

The lead 16 extends in the first direction x, as shown in FIGS. 3 and 4. In this embodiment, the lead 16 is located in the middle of the semiconductor device A10 in the second direction y. The lead 16 is an input terminal where the DC power (voltage) to be converted to power is inputted. The lead 16 is a negative or N terminal.

As shown in FIG. 10, the lead 16 has a main surface 161, a back surface 162, and end surfaces 163, 164. The main surface 161 faces the same side as the main surfaces 111 of the leads 11-14 in the thickness direction z and faces the semiconductor element 3. The main surface 161 is covered by the sealing resin 4. The semiconductor element 3 is supported on the main surface 161.

The back surface 162 faces the opposite side to the main surface 161 (the second side z2 in the thickness direction z). The back surface 162 is exposed from the sealing resin 4. In this embodiment, the main surface 161 and the back surface 162 are disposed to extend over the entire length of the semiconductor device A10 in the first direction x. The end surface 163 connects to both the main surface 161 and the back surface 162 and faces the second side x2 of the first direction x. The end face 164 connects to both the main surface 161 and the back surface 162 and faces the first side x1 of the first direction x. The end surface faces 163, 164 are exposed from the sealing resin 4.

In the lead 16, the main surface 161 on which semiconductor element 3 is supported may be silver plated, for example. In addition, the back surface 162 and the end surfaces 163, 164 exposed from the sealing resin 4 may be tin plated, for example. Instead of the tin plating, a plurality of metal plating may be employed, for example, nickel, palladium, and gold layered in this order.

The leads 17 are located in the middle of the semiconductor device A10 in the first direction x, as shown in FIGS. 3 and 4. Each lead 17 extends in the second direction y. One lead 17 is located on the first side y1 of the second direction y and the other lead 17 is located on the second side y2 of the second direction y. Each lead 17 is inputted with, for example, power (voltage) to drive a control circuit or with electrical signals to be transmitted to the control circuit.

As shown in FIG. 12, each lead 17 has a main surface 171, a back surface 172, and an end surface 173. The main surface 171 faces the same side as the main surfaces 111 of the leads 11-14 in the thickness direction z and faces the semiconductor element 3. The main surface 171 is covered by the sealing resin 4. The semiconductor element 3 is supported on the main surface 171.

The back surface 172 faces the opposite side of the main surface 171 (the second side z2 in the thickness direction z). The back surface 172 is exposed from the sealing resin 4. Each end surface 173 connects to both the main surface 171 and the back surface 172 and faces the second direction y. More specifically, the end surface 173 of one lead 17 faces the first side y1 of the second direction y and the end surface 173 of the other lead 17 faces the second side y2 of the second direction y. The end surfaces 173 are exposed from the sealing resin 4.

In each lead 17, the main surface 171 on which the semiconductor element 3 is supported may be silver plated, for example. In addition, the back surface 172 and end surfaces 173 exposed from the sealing resin 4 may be tin plated, for example. Instead of the tin plating, a plurality of metal plating may be employed, for example, nickel, palladium, and gold layered in this order.

The lead 18 is located near a corner of the semiconductor device A10 on the first side x1 in the first direction x and on the second side y2 in the second direction y, as shown in FIGS. 3 and 4. The lead 18 is inputted with electrical signals for transmission to the control circuit, for example. The lead 18 has a main surface 181, a back surface 182a, 182b, 182c, and end surfaces 183a, 183b, 184b, 183c. The main surface 181 faces the same side as the main surfaces 111 of the leads 11-14 in the thickness direction z and faces the semiconductor element 3. The main surface 181 is covered with the sealing resin 4. The semiconductor element 3 is supported on the main surface 181. The back surfaces 182a, 182b, 182c face the opposite side of the main surface 181 (the second side z2 in the thickness direction z). Each back surface 182a, 182b, 182c is exposed from the sealing resin 4. The back surface 182b is located at a corner of the semiconductor device A10 on the first side x1 in the first direction x and on the second side y2 in the second direction y. The back surface 182a is disposed on the first side y1 of the second direction y with respect to the back surface 182b. The back surface 182c is disposed on the second side x2 of the first direction x with respect to the back surface 182b. The end surface 183a connects to both the main surface 181 and the back surface 182a and faces the first side x1 of the first direction x. The end surface 183b is connected to both main surface 181 and back surface 182b and faces the first side x1 of the first direction x. The end surface 184b is connected to both main surface 181 and back surface 182b and faces the second side y2 of the second direction y. The end surface 183c connects to both main surface 181 and back surface 182c and faces the second side y2 of the second direction y. The end surfaces 183a, 183b, 184b, 183c are exposed from the sealing resin 4.

In the lead 18, the main surface 181 on which semiconductor element 3 is supported may be silver plated, for example. In addition, the back surfaces 182a, 182b, 182c and the end surfaces 183a, 183b, 184b, 183c exposed from the sealing resin 4 may be tin plated, for example. Instead of the tin plating, a plurality of metal plating may be employed, for example, nickel, palladium, and gold layered in that order.

A plurality of leads 19 are disposed on the second side y2 in the second direction y in the semiconductor device A10, as shown in FIGS. 3 and 4. The plurality of leads 19 are spaced apart from each other in the first direction x. An electrical signal is inputted to each lead 19, for example, for transmission to the control circuit. As shown in FIGS. 3, 4 and 13, each lead 19 has a main surface 191, a back surface 192 and an end surface 193. The main surface 191 faces the same side as the main surface 111 of the leads 11-14 in the thickness direction z and faces the semiconductor element 3. The main surface 191 is covered by the sealing resin 4. The semiconductor element 3 is supported on the main surface 191. The back surface 192 faces the opposite side of the main surface 191 (the second side z2 in the thickness direction z). The back surface 192 is exposed from the sealing resin 4. The end face 193 is connected to both the main surface 191 and the back surface 192 and faces the second side y2 of the second direction y. The end surface 193 is exposed from the sealing resin 4.

In each lead 19, the main surface 191 on which the semiconductor element 3 is supported may be silver plated, for example. In addition, the back surface 192 and end surfaces 193 exposed from the sealing resin 4 may be tin plated, for example. Instead of the tin plating, a plurality of metal plating may be employed, for example, nickel, palladium, and gold layered in this order.

The lead 20 is disposed on the second side x2 of the first direction x in the semiconductor device A10, as shown in FIGS. 3 and 4. The lead 20 is located in the second direction y, closer to the first side y1 of the second direction y. An electrical signal is inputted to the lead 20, for example, for transmission to the control circuit. The lead 20 has a main surface 201, a back surface 202, and an end surface 203. The main surface 201 faces the same side as the main surfaces 111 of the leads 11-14 in the thickness direction z and faces the semiconductor element 3. The main surface 201 is covered with the sealing resin 4. The semiconductor element 3 is supported by the main surface 201. The back surface 202 faces the opposite side of the main surface 201 (the second side z2 in the thickness direction z). The back surface 202 is exposed from the sealing resin 4. The end surface 203 is connected to both the main surface 201 and the back surface 202 and faces the second side x2 of the first direction x. The end face 203 is exposed from the sealing resin 4.

In the lead 20, the main surface 201 on which semiconductor element 3 is supported may be silver plated, for example. In addition, the back surface 202 and the end surfaces 203 exposed from the sealing resin 4 may be tin plated, for example. Instead of the tin plating, a plurality of metal plating may be employed, for example, nickel, palladium, and gold layered in this order.

A plurality of leads 21 are arranged on the first side y1 of the second direction y in the semiconductor device A10, as shown in FIGS. 3 and 4. The leads 21 are spaced apart from each other in the first direction x. An electrical signal is inputted to each lead 21, for example, for transmission to the control circuit. As shown in FIGS. 3, 4 and 13, each lead 21 has a main surface 211, a back surface 212 and an end surface 213. The main surface 211 faces the same side as the main surface 111 of the leads 11-14 in the thickness direction z and faces the semiconductor element 3. The main surface 211 is covered by the sealing resin 4. The semiconductor element 3 is supported on the main surface 211. The back surface 212 faces the opposite side of the main surface 211 (the second side z2 in the thickness direction z). The back surface 212 is exposed from the sealing resin 4. The end surface 213 is connected to both the main surface 211 and the back surface 212 and faces the first side y1 of the second direction y. The end surface 213 is exposed from the sealing resin 4.

In each lead 21, the main surface 211 on which the semiconductor element 3 is supported may be silver plated, for example. In addition, the back surface 212 and end surfaces 213 exposed from the sealing resin 4 may be tin plated, for example. Instead of the tin plating, a plurality of metal plating may be employed, for example, nickel, palladium, and gold layered in this order.

The lead 22 is disposed on the first side y1 of the second direction y in the semiconductor device A10, as shown in FIGS. 3 and 4. The lead 22 is located in the first direction x, closer to the first side x1 of the first direction x. An electrical signal is inputted to the lead 22, for example, for transmission to the control circuit. The lead 22 has a main surface 221, a back surface 222, and an end surface 223. The main surface 221 faces the same side as the main surfaces 111 of the leads 11-14 in the thickness direction z and faces the semiconductor element 3. The main surface 221 is covered by the sealing resin 4. The semiconductor element 3 is supported on the main surface 221. The back surface 222 faces the opposite side of the main surface 221 (the second side z2 in the thickness direction z). The back surface 222 is exposed from the sealing resin 4. The end surface 223 is connected to both the main surface 221 and the back surface 222 and faces the first side y1 of the second direction y. The end face 223 is exposed from the sealing resin 4.

In the lead 22, the main surface 221 on which semiconductor element 3 is supported may be silver plated, for example. In addition, the back surface 222 and the end surfaces 223 exposed from the sealing resin 4 may be tin platted, for example. Instead of the tin plating, a plurality of metal plating may be employed, for example, nickel, palladium, and gold layered in this order.

The lead 23 is disposed on the first side x1 of the first direction x in the semiconductor device A10, as shown in FIGS. 3 and 4. The lead 23 is located in the second direction y, closer to the first side y1 of the second direction y. An electrical signal is inputted to the lead 23, for example, for transmission to the control circuit. The lead 23 has a main surface 231, a back surface 232, and an end surface 233. The main surface 231 faces the same side as the main surfaces 111 of the leads 11-14 in the thickness direction z and faces the semiconductor element 3. The main surface 231 is covered by the sealing resin 4. The semiconductor element 3 is supported by the main surface 231. The back surface 232 faces the opposite side of the main surface 231 (the second side z2 in the thickness direction z). The back surface 232 is exposed from the sealing resin 4. The end face 233 is connected to both the main surface 231 and the back surface 232 and faces the first side x1 of the first direction x. The end face 233 is exposed from the sealing resin 4.

In the lead 23, the main surface 231 on which semiconductor element 3 is supported may be silver plated, for example. In addition, the back surface 232 and the end surfaces 233 exposed from the sealing resin 4 may be tin plated, for example. Instead of the tin plating, a plurality of metal plating may be employed, for example, nickel, palladium, and gold layered in this order.

Each lead 25 is located in one of the four corners of the semiconductor device A10, as viewed in the thickness direction z, as shown in FIGS. 3 and 4. In this embodiment, three leads 25 are employed. The three leads 25 are located, in the semiconductor device A10, at respective three corners: a corner of the first side x1 of the first direction x and the first side y1 of the second direction y; a corner of the second side x2 of the first direction x and the first side y1 of the second direction y; and a corner of the second side x2 of the first direction x and the second side y2 of the second direction y. Each lead 25 is not conducting to the semiconductor element 3 and is therefore a “dummy” terminal. Each lead 25 has a main surface 251, a back surface 252, and two end surfaces 253, 254. The main surface 251 faces the same side as the main surfaces 111 of the leads 11-14 in the thickness direction z. The main surface 251 is covered by the sealing resin 4. The back surface 252 faces the opposite side of the main surface 251 (the second side z2 in the thickness direction z). The back surface 252 is exposed from the sealing resin 4. The end surface 253 is connected to both the main surface 251 and the back surface 252 and faces in the first direction x. The end surface 254 is connected to both the main surface 251 and the back surface 252 and faces in the second direction y. The end surfaces 253, 254 are exposed from the sealing resin 4.

In each lead 25, the back surface 252 and the end surfaces 253, 254 exposed from the sealing resin 4 may be tin plated, for example. Instead of the tin plating, a plurality of metal plating may be employed, for example, nickel, palladium, and gold layered in this order.

As shown in FIG. 4, the plurality of leads 21, one lead 17 (on the first side y1 of the second direction y), and the lead 22 have their respective back surfaces 212, 172, 222 lined up along the edge of the bottom surface 42 of the sealing resin 4 on the first side y1 of the second direction y. The plurality of leads 19, the other lead 17 (on the second side y2 of the second direction y), and the lead 18 have their respective back surfaces 192, 172, 182c lined up along the edge of the bottom surface 42 of the sealing resin 4 on the second side y2 of the second direction y. The leads 11, 12, 15, 16, 18, 23 have their respective back surfaces 182a, 112, 153, 162, 112, 232 lined up along the edge of the bottom surface 42 of the sealing resin 4 on the first side x1 of the first direction x. The leads 13, 14, 15, 16, 20 have their respective back surfaces 112, 152, 162, 112, 202 lined up along the edge of the bottom surface 42 of the sealing resin 4 on the second side x2 of the first direction x. The leads 25 have an end surface 253 facing in the first direction x and an end surface 254 facing in the second direction y. Each lead 25 is a dummy terminal that does not conduct to semiconductor element 3. The lead 18 has an end surface 183b facing in the first direction x and an end surface 184b facing in the second direction y. The lead 18 is conductive to the semiconductor element 3.

The arrangement, shape, and function of the leads 11-25 are not limited. The conductive member 1 may not have all of the above leads 11-25, and may have other additional leads. The layout of the conductive member 1 may be designed in various ways.

The sealing resin 4 covers a portion of the conductive member 1, and the semiconductor element 3. The material of the sealing resin 4 is an insulator, for example, a black epoxy resin. The sealing resin 4 is rectangular in shape as viewed in the thickness direction z. In this embodiment, the external shape of the sealing resin 4 may be the same as the external shape of the semiconductor device A10 as viewed in the thickness direction z. The sealing resin 4 has a top surface 41, a bottom surface 42, a first side surface 431, a second side surface 432, a third side surface 433, and a fourth side surface 434, as shown in FIGS. 5 to 8.

As shown in FIGS. 9 through 13, the top surface 41 faces the same side (first side z1 of thickness direction z) as the main surfaces 111 of the leads 11-14 in the thickness direction z. As shown in FIGS. 5 to 8, the bottom surface 42 faces the opposite side of the top surface 41 (the second side z2 in the thickness direction z). The top surface 41 and the bottom surface 42 are rectangular. As shown in FIGS. 4 and 9 to 13, the following back surfaces are exposed from the bottom surface 42: the back surfaces 112, 113 of the leads 11-14; the back surfaces 152, 153 of the leads 15; the back surface 162 of the lead 16; the back surfaces 172 of the leads 17; the back surfaces 182a, 182b, 182c of the lead 18; the back surfaces 192 of the leads 19; the back surface 202 of the lead 20; the back surfaces 212 of the leads 21; the back surface 222 of the lead 22; the back surface 232 of the lead 23; and the back surfaces 252 of the leads 25.

The first side surface 431, the second side surface 432, the third side surface 433 and the fourth side surface 434 are connected to and perpendicular to (which may include the case of “substantially perpendicular to”) the top surface 41 and the bottom surface 42. As shown in FIGS. 5 and 6, the first side surface 431 and the second side surface 432 are spaced apart from each other in the first direction x. The first side surface 431 faces the first side x1 of the first direction x. The second side surface 432 faces the second side x2 of the first direction x. As shown in FIG. 4, FIG. 7, and FIGS. 9 through 11, the end surfaces 115 of the leads 11, 12, the end surface 156 of the lead 15, the end surface 164 of the lead 16, the end surfaces 183a, 183b of the lead 18, the end surface 233 of the lead 23, and the end surface 253 of the lead 25 are exposed from the first side surface 431. These end surfaces are flush with the first side surface 431. As shown in FIG. 4, FIGS. 8 through 11, the end surfaces 115 of the leads 13, 14, the end surface 155 of the lead 15, the end surface 163 of the lead 16, the end surface 203 of the lead 20, and the end surfaces 253 of the leads 25 are exposed from the second side surface 432. These end surfaces are flush with the second side surface 432.

The third side surface 433 and the fourth side surface 434 are connected to the first side surface 431 and the second side surface 432. As shown in FIGS. 7 and 8, the third side surface 433 and the fourth side surface 434 are spaced from each other and face away from each other in the second direction y. The third side surface 433 faces the first side y1 of the second direction y. The fourth side surface 434 faces the second side y2 of the second direction y. As shown in FIGS. 4, 6, 12 and 13, the end surface 173 of one lead 17, the end surfaces 213 of the leads 21, the end surface 223 of the lead 22, and the end surfaces 254 of the leads 25 are exposed from the third side surface 433. These end surfaces are flush with the third side surface 433. As shown in FIGS. 4, 5, 12, and 13, the end surface 173 of the other lead 17, the end surfaces 184b, 183c of the lead 18, the end surfaces 193 of the leads 19, and the end surface 254 of the lead 25 are exposed from the fourth side surface 434. These end surfaces are flush with the fourth side surface 434.

The sealing resin 4 has four corners 46a, 46b, 46c, 46d as shown in FIGS. 1 to 3. Each corner 46a, 46b, 46c, 46d is located at one of the four corners of the top surface 41. The corners 46a and 46b are located on the first side x1 of the first direction x. More specifically, the corner 46a is located on the first side x1 of the first direction x and on the first side y1 of the second direction y, while the corner 46b is located on the first side x1 of the first direction x and on the second side y2 of the second direction y. The corner 46c and 46d are located on the second side x2 of the first direction x. More specifically, the corner 46c is located on the second side x2 of the first direction x and on the first side y1 of the second direction y, while the corner 46d is located on the second side x2 of the first direction x and on the second side y2 of the second direction y.

The semiconductor element 3 is supported by a plurality of leads 11-23, as shown in FIG. 3 and FIGS. 9-13. The semiconductor element 3 is covered by the sealing resin 4. The semiconductor element 3 includes a semiconductor substrate 31, a semiconductor layer 32, and a plurality of electrodes 33 and 34.

As shown in FIGS. 9 through 13, the semiconductor substrate 31 supports the semiconductor layer 32, the electrodes 33 and 34. The constituent material of the semiconductor substrate 31 is, for example, silicon (Si) or silicon carbide (SiC).

In the thickness direction z, the semiconductor substrate 31 has a side facing the main surfaces 111 of the leads 11-14, and the semiconductor layer 32 is disposed on this side. The semiconductor layer 32 includes a number of p-type and n-type semiconductors depending on differences in the amount of doped elements. The semiconductor layer 32 comprises a switching circuit and a control circuit that conducts to the switching circuit. The switching circuit is composed of, for example, a Metal-Oxide-Semiconductor Field-Effect Transistor (MOSFET) or Insulated Gate Bipolar Transistor (IGBT). In the semiconductor device A10, the switching circuit may be divided into two regions, i.e., a high-voltage region (upper arm circuit) and a low-voltage region (lower arm circuit). Each region may include an n-channel MOSFET. The control circuit may be provided with a gate driver to drive the switching circuit and a bootstrap circuit for the high-voltage region of the switching circuit. The control circuit may also perform a controlling operation to drive the switching circuit properly. The semiconductor layer 32 may also include a wiring layer (not shown) for electrically connecting the switching circuit and the control circuit.

As shown in FIGS. 9 to 13, the electrodes 33, 34 are provided on the side of the semiconductor layer 32 that faces the main surfaces 111 of the leads 11-14 in the thickness direction z. The electrodes 33, 34 are in contact with the semiconductor layer 32.

The electrodes 33 are conductive to the switching circuit of the semiconductor layer 32. Each electrode 33 is conductively bonded to a corresponding one of the main surfaces 111 of the leads 11-14, the main surface 151 of the lead 15 and the main surface 161 of the lead 16. Thus, the leads 11-16 are conductive to the switching circuit. In this embodiment, at least one electrode 33 overlaps with the back surfaces 113 of the leads 11-14 as viewed in the thickness direction z.

The electrodes 34 conduct to the control circuit of the semiconductor layer 32. Each electrode 34 is conductively bonded to a corresponding one of the main surfaces 171 of the leads 17, the main surface 181 of the lead 18, the main surfaces 191 of the leads 19, the main surface 201 of the lead 20, the main surfaces 211 of the leads 21, the main surface 221 of the lead 22, and the main surface 231 of the lead 23. Thus, the leads 17-23 are conductive to the control circuit. The constituent material of the electrodes 33, 34 may include, for example, copper.

The semiconductor element 3 is rectangular in shape as viewed in the thickness direction z, as shown in FIGS. 2 and 3. The semiconductor element 3 has an element main surface 305, an element back surface 306, and element side surfaces 301-304.

The semiconductor element 3 is rectangular in shape as viewed in the thickness direction z, as shown in FIGS. 2 and 3. The semiconductor element 3 has an element main surface 305, an element back surface 306, and element side surfaces 301-304. As shown in FIGS. 9 to 13, the element main surface 305 and the element back surface 306 face opposite each other in the thickness direction z. The element main surface 305 is the face of the semiconductor layer 32, where electrodes 33 and 34 are located. In this embodiment, the element main surface 305 faces the second side z2 and is opposite the main surfaces 111 of the leads 11-14. The element back surface 306 is the side of the semiconductor substrate 31 opposite the semiconductor layer 32. In this configuration, the element back surface 306 faces the first side z1. The element main surface 305 and the element back surface 306 are rectangular.

The element side surfaces 301-304 are connected to the element main surface 305 and element back surface 306 and are perpendicular to the element main surface 305 and the element back surface 306. As shown in FIGS. 2 and 3, the element side surface 301 and the element side surface 302 are spaced from each other and face away from each other. The element side surface 303 and the element side surface 304 connect to both the element side surface 301 and the element side surface 302. The element side surface 303 and the element side surface 304 are spaced apart from each other and face opposite sides of each other. In this embodiment, the outer edges of the semiconductor substrate 31 and the semiconductor layer 32, as viewed in the thickness direction z, comprise the element side surfaces 301-304.

In this embodiment, the rectangular semiconductor element 3 is not arranged parallel to the rectangular sealing resin 4, but is inclined as viewed in the thickness direction. The element side surface 301 is oriented inclined from the first side x1 in the first direction x toward the second side y2 in the second direction y. In other words, the element side surface 301 is inclined with respect to the first side surface 431 of the sealing resin 4. The element side surface 302 is oriented inclined from the second side x2 of the first direction x toward the first side y1 of the second direction y. In other words, the element side surface 302 is inclined with respect to the second side surface 432 of the sealing resin 4. The element side surface 303 is oriented inclined from the first side y1 of the second direction y toward the first side x1 of the first direction x. In other words, the element side surface 303 is inclined with respect to the third side surface 433 of the sealing resin 4. The element side surface 304 is oriented inclined from the second side y2 of the second direction y toward the second side x2 of the first direction x. In other words, the element side surface 304 is inclined with respect to the fourth side surface 434 of the sealing resin 4.

As shown in FIG. 2, as viewed in the thickness direction z, the edge 305a of the element main surface 305 connected to the element side surface 301 is inclined with respect to the edge 41a of the top surface 41 connected to the first side surface 431. The inclination angle α of the edge 305a with respect to the edge 41a may be greater than 0° and less than 90°. If the inclination angle α is greater than 45°, the angle of inclination of the edge 305a with respect to the edge 41b of the top surface 41 connected to the fourth side surface 434 is less than 45°. In this way, as viewed in the thickness direction z, the inclination angle of an edge of the element main surface 305 with respect to an edge of the top surface 41 is greater than 0° and less than 45°. In this embodiment, the above-noted inclination angle is 45°, and thus, the distances between the respective corners 46a, 46b, 46c, 46d and the semiconductor element 3 can be the largest as viewed in the thickness direction z. The inclination angle α is not limited to 45°. Preferably, as viewed in the thickness direction z, the distance D1 between the corner 46b and the edge 305a may be at least 25% of the diagonal length D2 of the top surface 41 of the sealing resin 4. This configuration may hold for the distance between each corner 46a, 46c, 46d and the closest edge corresponding to the edge.

Next, effects of the semiconductor device A10 will be described below.

According to this embodiment, the semiconductor device A10 has the edge 305a of the element main surface 305 that is inclined with respect to the edge 41a of the top surface 41. As a result, the distance between a corner of the semiconductor device A10 and the semiconductor element 3 is appropriately longer, as viewed in the thickness direction z, compared to the case where the edge 305a is parallel to the edge 41a (referred to as “parallel arrangement” below). Therefore, the semiconductor device A10 can enjoy improved mounting reliability compared to the case employing the parallel arrangement.

Further, according to this embodiment, the inclination angle α of the edge 305a with respect to the edge 41a is 45°. This is advantageous to causing the distance between a corner of the semiconductor device A10 and the semiconductor element 3 to be maximized, as viewed in the thickness direction z. Therefore, the semiconductor device A10 can enjoy improved mounting reliability.

### First Variation of the First Embodiment

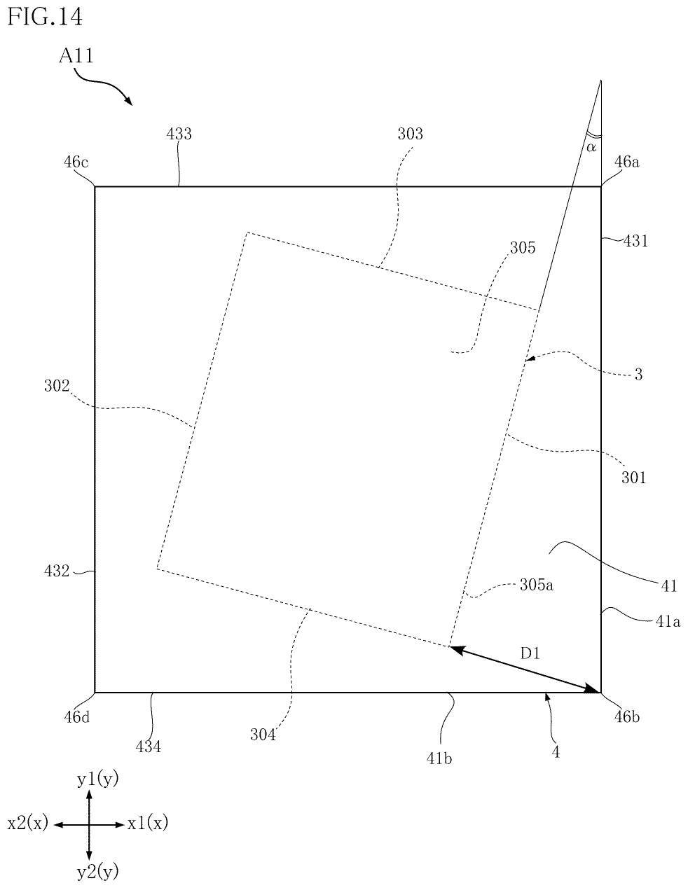

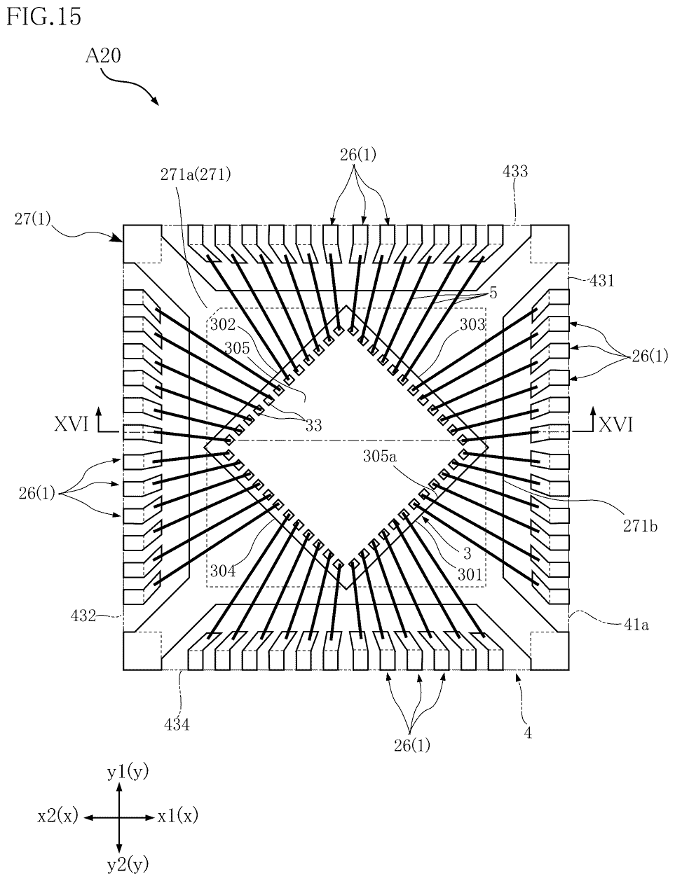

FIG. 14 shows a semiconductor device A11 according to a first variant of the first embodiment. FIG. 14 is a plan view of the semiconductor device A11, corresponding to FIG. 2. In the drawings after FIG. 14, elements identical or similar to those of the above semiconductor device A10 are marked with the same symbols, and their description may be omitted.

In the semiconductor device A11, the inclination angle α of the edge 305a relative to the edge 41a is 15°. Thus, compared to the case where the inclination angle α is 45°, the distance D1 between the corner 46b and the edge 305a is smaller as viewed in the thickness direction z. In this case, however, the distance D1 is sufficiently large compared to that in the parallel arrangement discussed above.

The inclination angle α is not limited, as long as it is greater than 0° and less than 90° as mentioned above, and the distance D1 is relatively large except in the parallel arrangement (the inclination angle α is 0°). It should be noted that the distance D1 is not much different from that of the parallel arrangement when the inclination angle α is smaller than 5°. Hence, preferably, the inclination angle α may not be less than 5°.

### Second Embodiment

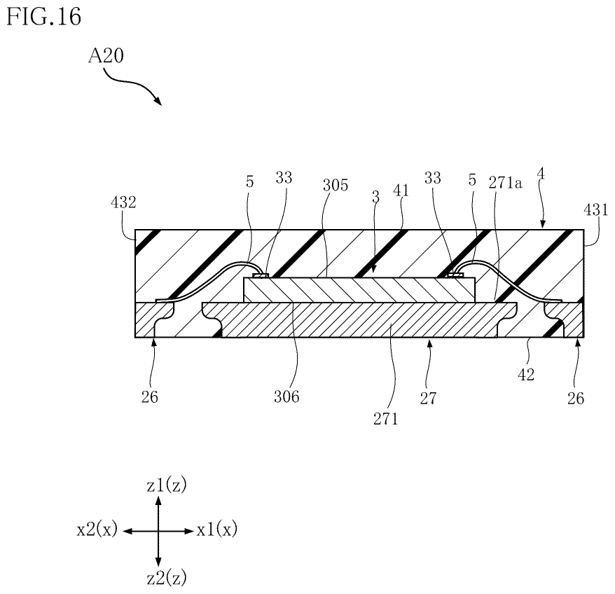

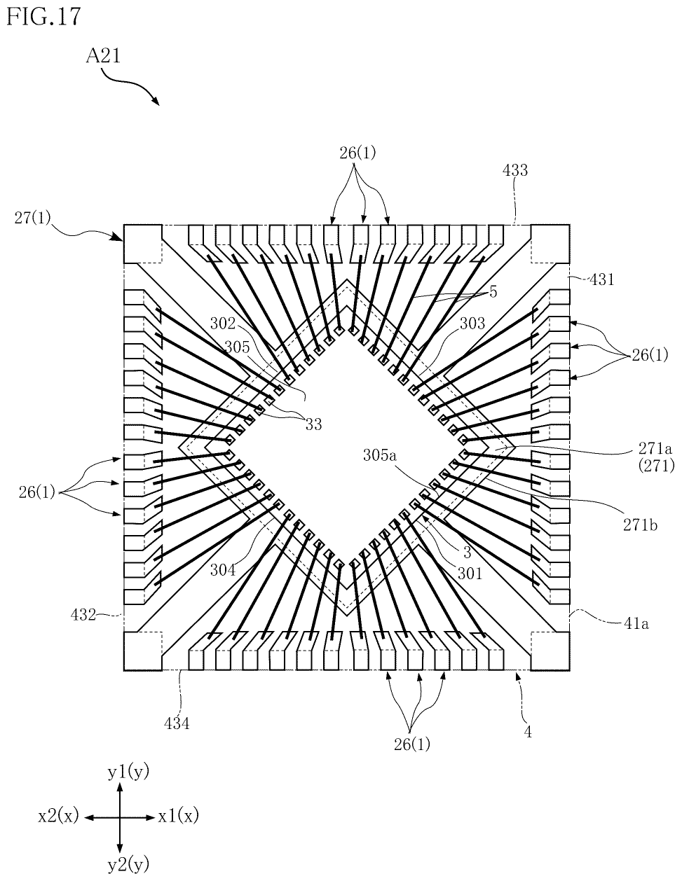

FIGS. 15 and 16 show a semiconductor device A20 in accordance with a second embodiment of the present disclosure. FIG. 15 is a plan view of the semiconductor device A20, corresponding to FIG. 3. FIG. 16 is a cross-sectional view along the XVI-XVI line of FIG. 15, corresponding to FIG. 9, for example. FIG. 15 shows the sealing resin 4 as being transparent for convenience of understanding. The semiconductor device A20 differs from that of the first embodiment in the orientation of the semiconductor element 3 in the thickness direction z. The other configurations and the operation of the second embodiment are the same as those of the first embodiment. It should be noted that configurations of the first embodiment and those of the respective variations may be combined as appropriate.

In the semiconductor device A20, the conductive member 1 has a lead 27 and a plurality of leads 26. The lead 27 has a die pad 271 on which the semiconductor element 3 is mounted. The die pad 271 has a main surface 271a facing the first side z1 in the thickness direction z. As viewed in the thickness direction z, there are four terminal sections provided at the four corners of the semiconductor device A20, so as to be connected to the die pad 271. The main surface 271a of the die pad 271 is rectangular. As viewed in the thickness direction z, each edge of the main surface 271a is parallel to one of the edges of the top surface 41 of the sealing resin 4. For example, the edge 271b of the main surface 27la on the first side x1 of the first direction x is parallel to the edge 41a of the top surface 41. The semiconductor element 3 is bonded to the main surface 271a of the die pad 271 with the element main surface 305 facing the first side z1 of the thickness direction z. As with the semiconductor device A10, in the semiconductor element 3 of this embodiment, the edge 305a of the element main surface 305 is inclined with respect to the edge 41a of top surface 41, as viewed in the thickness direction z. The plurality of leads 26 are located at both ends of the semiconductor device A20 in the first direction x and in the second direction y, respectively, with a number of leads at each end. Each electrode 33 of the semiconductor element 3 is conductively connected by a wire 5 to one of the leads 26.

In this embodiment, the edge 305a of the element main surface 305 is inclined with respect to the edge 41a of the top surface 41. Hence, compared to the parallel arrangement, the distance between the corners of the semiconductor device A20 and the semiconductor element 3 are relatively longer as viewed in the thickness direction z. Thus, the semiconductor device A20 can improve mounting reliability compared to the case where the parallel arrangement is employed. The semiconductor device A20 may be equipped with configurations common or similar to those of the semiconductor device A10, so that the same effects as those of the semiconductor device A10 can be achieved.

### First Variation of Second Embodiment

FIG. 17 shows a semiconductor device A21 for the first variation of the second embodiment. FIG. 17 is a plan view of the semiconductor device A21, corresponding to Figure. 3. For convenience of understanding, FIG. 17 shows the sealing resin 4 as being transparent.

In the semiconductor device A21, the main surface 271a of the die pad 271 has four edges parallel to the respective edges of the element main surface 305 of the semiconductor element 3. as viewed in the thickness direction z, For example, the edge 271b of the main surface 271a, on the first side x1 in the first direction x and on the second side y2 in the second direction y, is parallel to the edge 305a of the element main surface 305.

### Second Variation of Second Embodiment

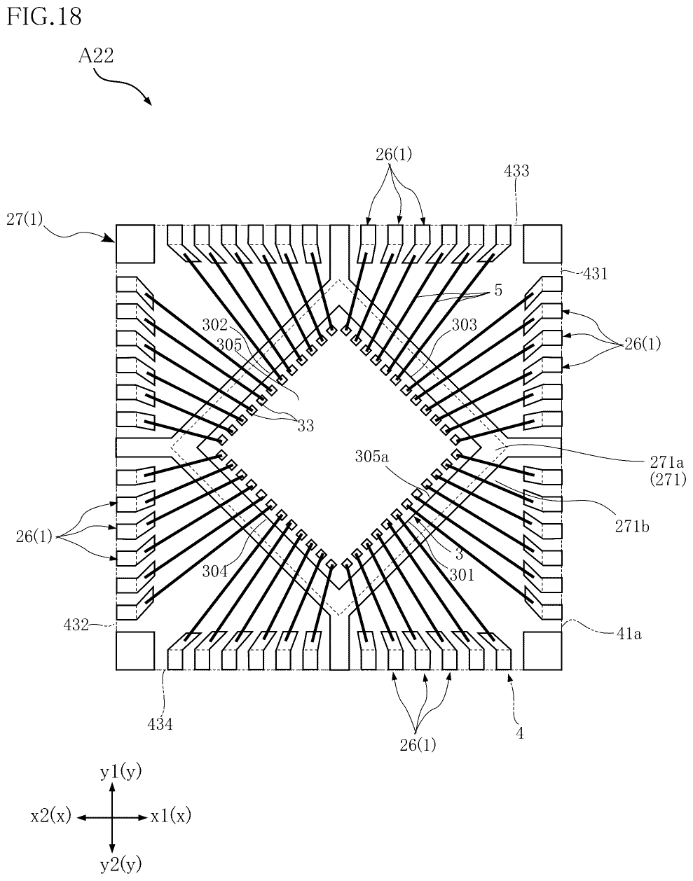

FIG. 18 shows a semiconductor device A22 for a second variation of the second embodiment. FIG. 18 is a plan view of the semiconductor device A22, corresponding to FIG. 3. FIG. 18 shows the sealing resin 4 as being transparent for convenience of understanding.

In the semiconductor device A22, the die pad 271 is not connected to the terminal sections located at the four corners of the semiconductor device A22. Instead, the die pad 271 is fixed by suspension leads exposed from the first side surface 431, the second side surface 432, the third side surface 433 and the fourth side surface 434 of the sealing resin 4.

As understood from these variations, regardless of the shape or configuration of the die pad 271, the semiconductor element 3 may be mounted on the die pad 271 such that the edge 305a of the element main surface 305 is inclined to the edge 41a of the top surface 41, as viewed in the thickness direction z. Further, as understood from the second embodiment, the orientation of the semiconductor element 3 in the thickness direction z may be arbitrary. That is, the element main surface 305 may face the first side z1 of the thickness direction z or the second side z2.

In the first and second embodiments, the package type of the semiconductor device A10 (and A11, A20, A21, A22) is QFN, but the present disclosure is not limited to this. The package type of the semiconductor device A10 (A11, A20, A21, A22) may be a QFP with leads protruding from the side surfaces 431, 432, 433 and 434.

### Third Embodiment

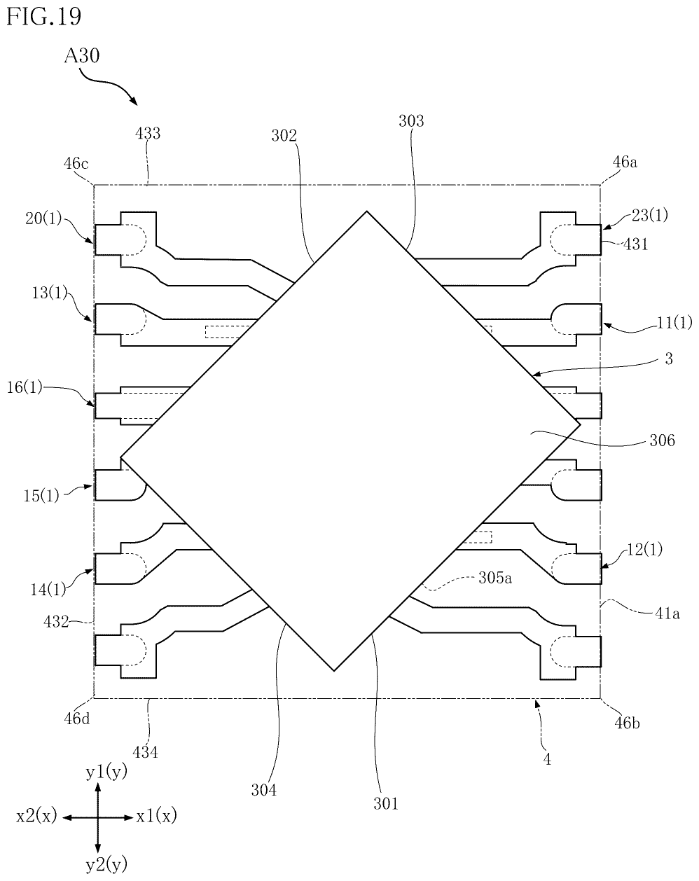

FIG. 19 shows a semiconductor device A30 in accordance with a third embodiment of the present disclosure. FIG. 19 is a plan view of the semiconductor device A30, corresponding to FIG. 3. FIG. 19 shows the sealing resin 4 as being transparent for convenience of understanding. The semiconductor device A30 differs from that of the first embodiment in the package type. The configurations and operation of the other parts of this embodiment may be the same as or similar to those of the first embodiment. In this embodiment, the above-noted first and second embodiments and their variations may be combined as appropriate.

In the semiconductor device A30, the package type is a DFN (Dual Flat Non-Lead Package). Thus, the semiconductor device A30 does not have leads 17, 21, 22 and 25 exposed from the third side surface 433 of the sealing resin 4, nor leads 17, 18, 19, and 25 exposed from the fourth side surface 434 of the sealing resin 4.

In this embodiment, the edge 305a of the element main surface 305 is inclined with respect to the edge 41a of the top surface 41. Thus, compared to the parallel arrangement, the distance between the corners of the semiconductor device A30 and the semiconductor element 3 is longer as viewed in the thickness direction z. Hence, the semiconductor device A30 can enjoy improved mounting reliability compared to the parallel arrangement. Further, the semiconductor device A30 may have common configurations with those of the semiconductor device A10, so that the same or similar effects can be ensured.

In the third embodiment described above, the package type of semiconductor device A30 is DFN, but the present disclosure is not limited to this. The package type of the semiconductor device A30 may be a Small Outline Package (SOP) with leads protruding from the first and second side surfaces 431, 432. In the third embodiment, the element main surface 305 of the semiconductor element 3 faces the second side z2 of the thickness direction z, but the present disclosure is not limited to this. The element main surface 305 of the semiconductor element 3 may face the first side z1 of the thickness direction z.

### Fourth Embodiment

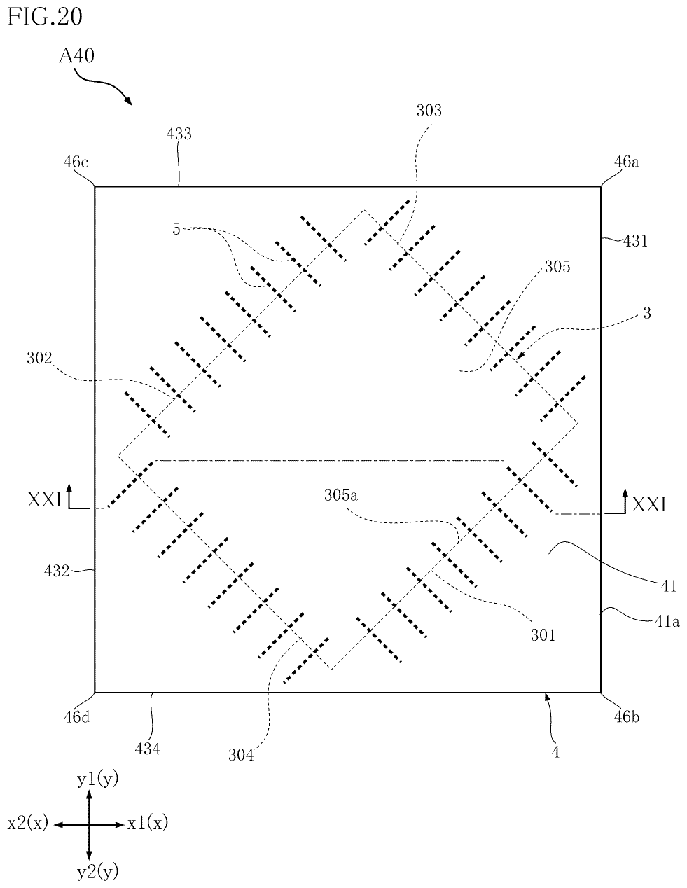

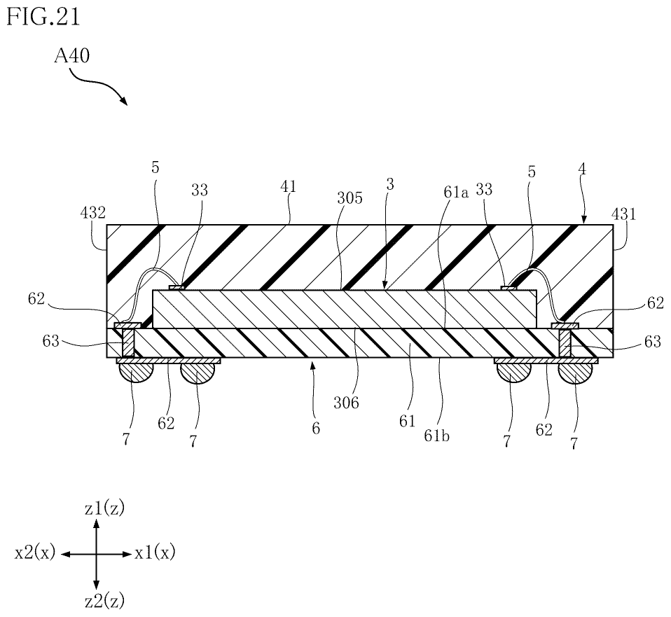

FIGS. 20 and 21 show a semiconductor device A40 in accordance with a fourth embodiment of the present disclosure. FIG. 20 is a plan view of the semiconductor device A40, corresponding to FIG. 2. FIG. 21 is a cross-sectional view along the XXI-XXI line of FIG. 20, corresponding to FIG. 9, for example. The semiconductor device A40 differs from the first embodiment in its package type. The configurations and operation of the other parts of this embodiment are the same as or similar to those of the first embodiment. In this embodiment, the configurations of the first through three embodiments and their variations may be combined as appropriate.

The semiconductor device A40 has a package type of Ball Grid Array (BGA). In the semiconductor device A40, as shown in FIG. 21, the conductive member 1 includes a wiring substrate 6 and a plurality of bumps 7, instead of leads 11-25. The wiring substrate 6 is made up of a base member 61, wiring layers 62, and vias 63. The base member 61 is made of an insulating material, for example epoxy resin, and has a main surface 61a facing the first side z1 in the thickness direction z and a back surface 61b facing the second side z2. The wiring layers 62 are disposed on the main surface 61a and the back surface 61b, respectively. Each via 63 is a through-hole extending through the base member 61 from the main surface 61a to the back surface 61b, with a copper conductor, for example, is provided in the through-hole. The vias 63 electrically connect the wiring layer 62 on the main surface 61a to the other wiring layer 62 on the back surface 61b. The semiconductor element 3 is bonded to the main surface 61a of the base member 61 with the element main surface 305 facing the first side zl of the thickness direction z. As in the semiconductor device A10, the semiconductor element 3 is, as viewed in the thickness direction z, disposed so that the edge 305a of the element main surface 305 is inclined with respect to the edge 41a of top surface 41. Each electrode 33 of the semiconductor element 3 is electrically connected to the wiring layer 62 on the main surface 61a by wires 5. The bumps 7 are a spherical-shaped member of copper, for example, and are disposed on the wiring layer 62 of the back surface 61b.

In this embodiment again, the edge 305a of the element main surface 305 is inclined with respect to the edge 41a of the top surface 41. Thus, compared to the parallel arrangement, the distance between the corners of the semiconductor device A40 and the semiconductor element 3 is longer as viewed in the thickness direction z. Hence, the semiconductor device A40 can enjoy improved mounting reliability compared to the parallel arrangement. The semiconductor device A40 may have common configurations with the semiconductor device A10, so that it has the same or similar effects as the semiconductor device A10.

In the fourth embodiment, regarding the semiconductor element 3, the element main surface 305 faces the first side z1 of the thickness direction z, but the present disclosure is not limited to this. The semiconductor element 3 may be mounted so that the element main surface 305 faces the second side z2 of the thickness direction z.

As seen from the third and fourth embodiments, the package type of the present disclosure is not limited to the QFN nor QFP, and various types of packaging may be applicable to the devices according to the present disclosure.

### Fifth Embodiment

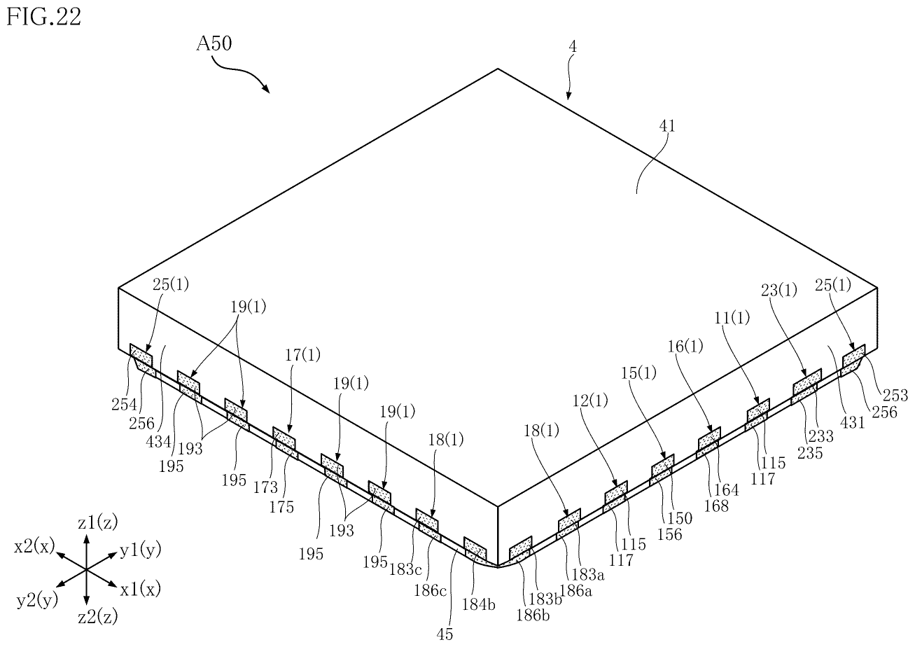

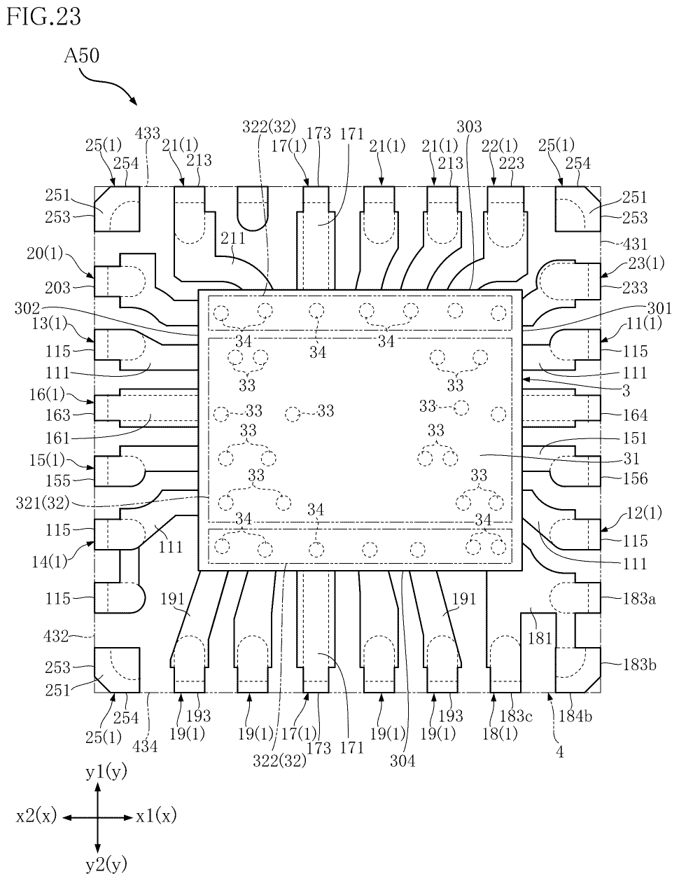

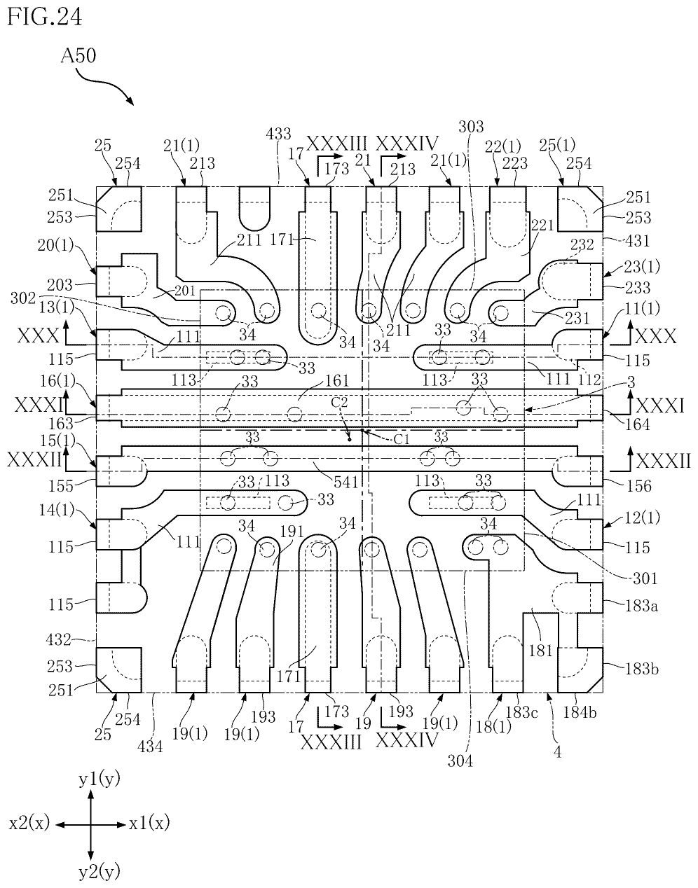

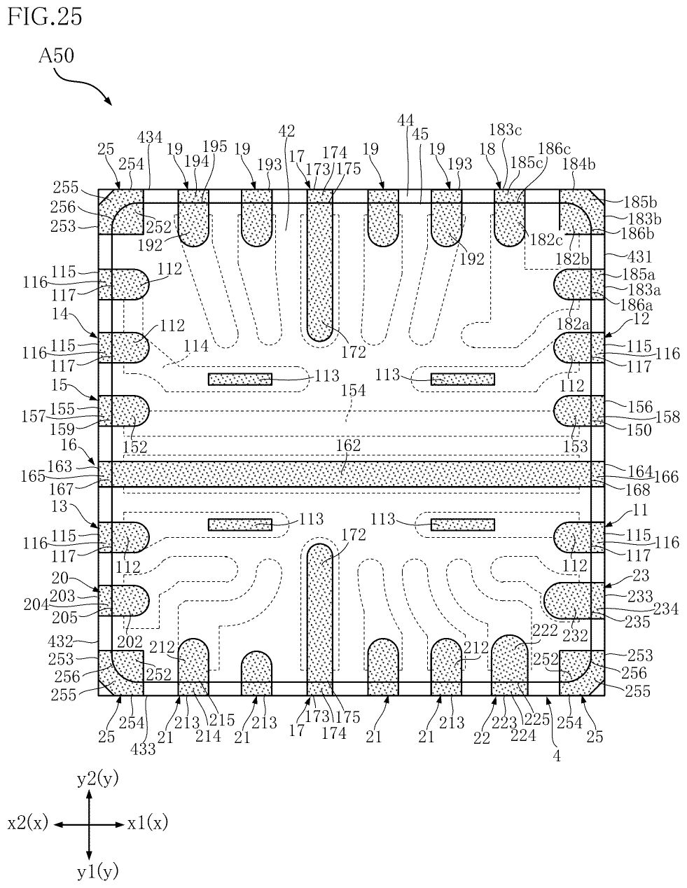

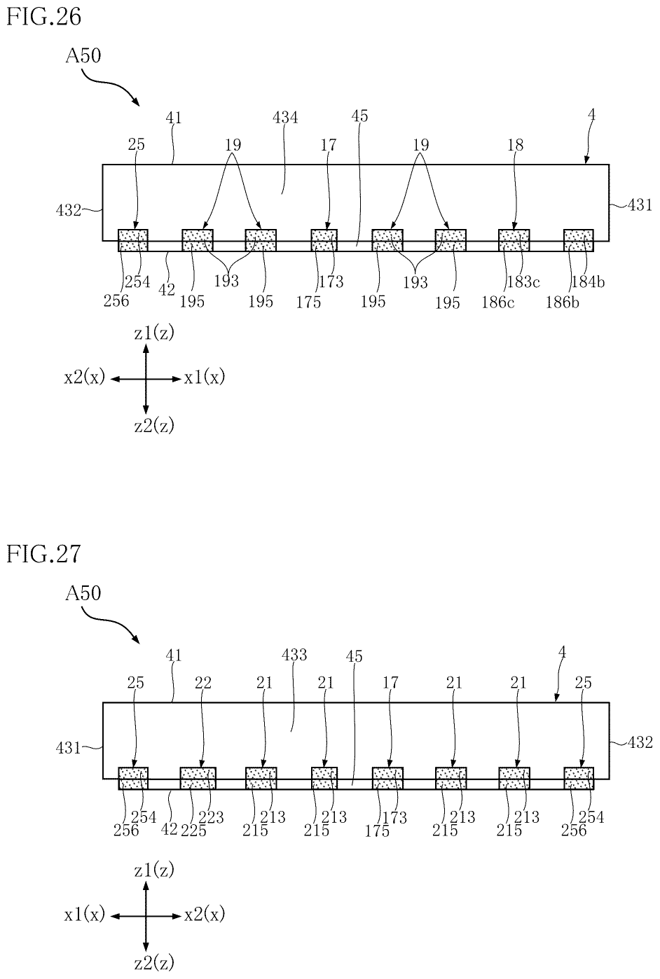

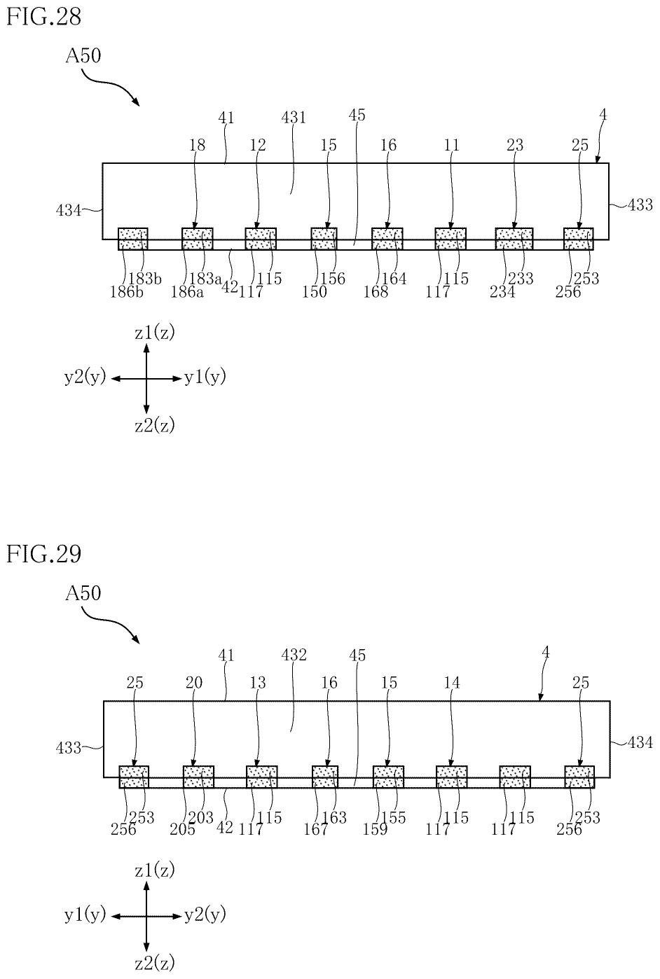

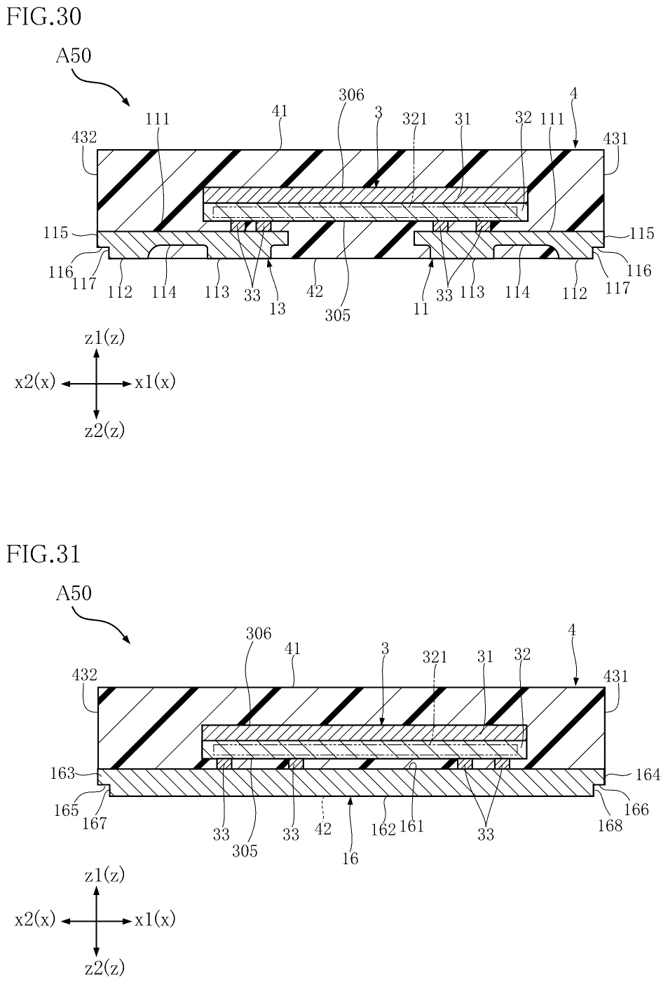

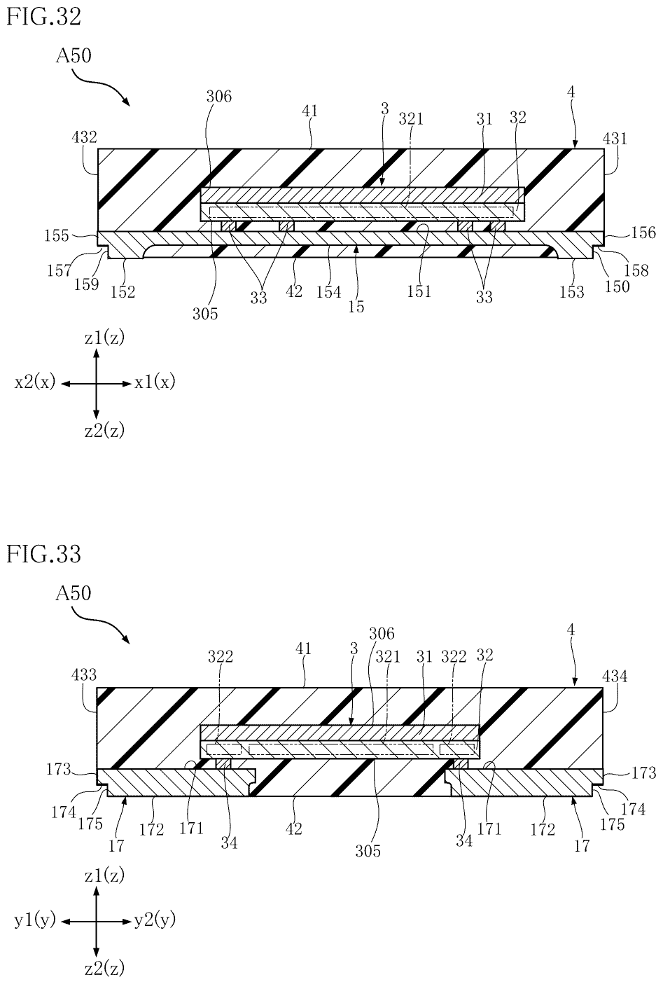

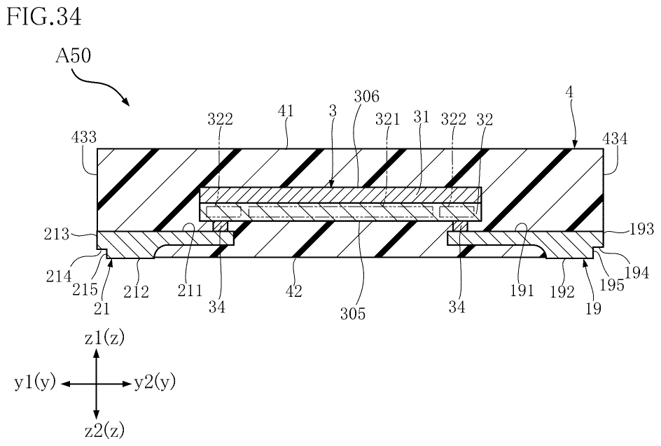

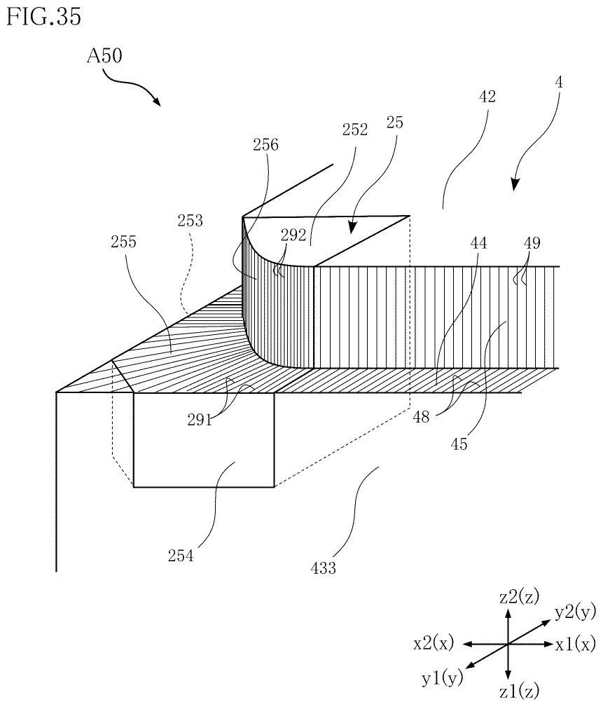

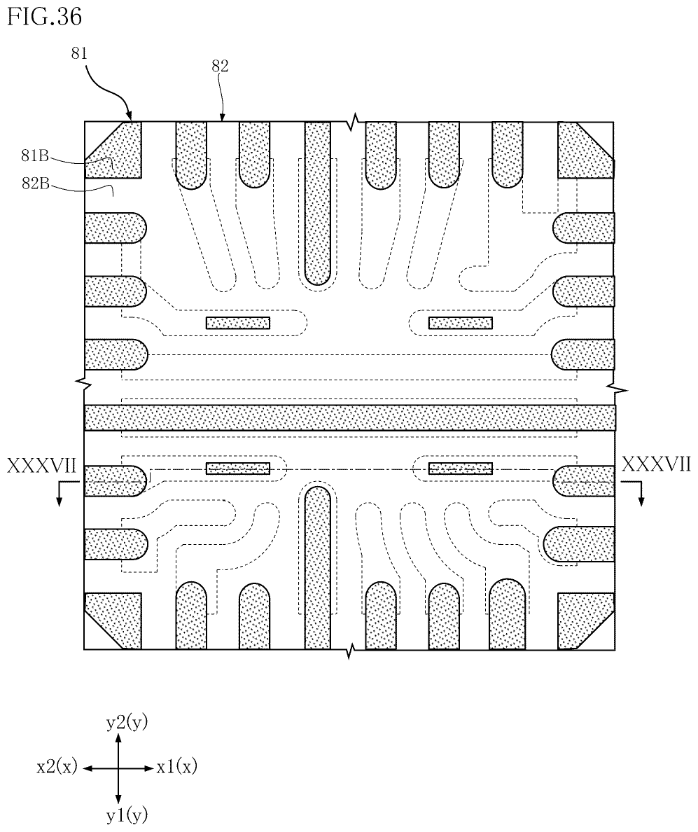

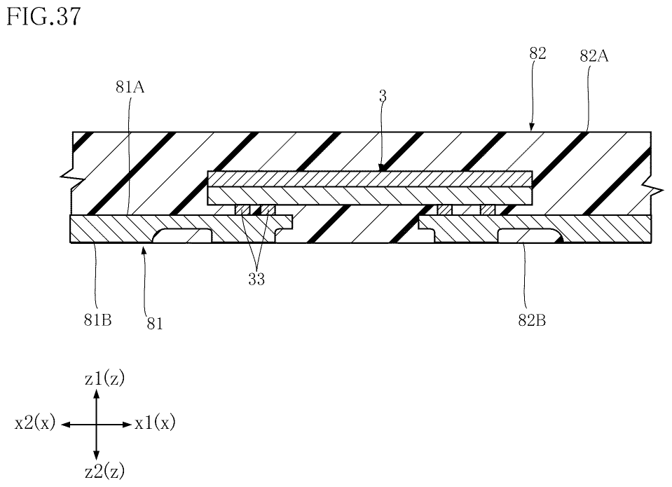

Based on FIGS. 22 to 35, a semiconductor device A50 in accordance with a fifth embodiment of the present disclosure will be described. FIG. 22 is a diagram showing the semiconductor device A50. FIG. 23 is a plan view showing the semiconductor device A50. FIG. 23 shows the sealing resin 4 as being transparent for convenience of understanding. FIG. 24 is a plan view showing the semiconductor device A50. FIG. 24 shows the semiconductor element 3 and the sealing resin 4 as being transparent for convenience of understanding. FIG. 25 is a bottom view of the semiconductor device A50. FIG. 26 is a front view of the semiconductor device A50. FIG. 27 is a rear view showing the semiconductor device A50. FIG. 28 is a right side view showing the semiconductor device A50. FIG. 29 is a left side view showing the semiconductor device A50. FIG. 30 is a cross-sectional view along the XXX-XXX line of FIG. 24. FIG. 31 is a cross-sectional view along the XXXI-XXXI line of FIG. 24. FIG. 32 is a cross-sectional view along the XXXII-XXXII line of FIG. 24. FIG. 33 is a cross-sectional view along the XXXIII-XXXIII line of FIG. 24. FIG. 34 is a cross-sectional view along the XXXIV-XXXVI line of FIG. 24. FIG. 35 is a partially enlarged diagram showing the semiconductor device A50. In the fifth embodiment, explanations may be omitted for configurations same as or similar to those described with the first through fourth embodiments.

As shown in FIGS. 24, 25, and 30, each of the plurality of leads 11, 12, 13, and 14 has a displacement or offset back surface 116 and a connection surface 117.

The displacement back surface 116 faces the opposite side (second side z2 in the thickness direction z) of the main surface 111. The displacement back surface 116 is located closer to the first side z1 in the thickness direction z than the back surface 112, and is closer to the main surface 111 than is the back surface 112. The displacement back surface 116 is connected to the end surface 115 and is exposed from the sealing resin 4. The connection surface 117 is connected to the back surface 112 and the displacement back surface 116, and is exposed from the sealing resin 4. In this embodiment, the connection surface 117 is perpendicular to the back surface 112. As shown in FIG. 25, lead 14 has two back surfaces 112, two end surfaces 115, two displacement back surfaces 116, and two connection surfaces 117. One group of the back surface 112, the end surface 115, the displacement back surface 116, and the connection surface 117 is spaced apart from the other group of the back surface 112, the end surface 115, the displacement back surface 116, and the connection surface 117 in the second direction y.

In each lead 11-14, the back surfaces 112, 113, the displacement back surface 116, and the connection surface 117, which are exposed from the sealing resin 4, are tin plated, for example. Instead of the tin plating, a number of metal plating may be employed, for example, with layers of nickel, palladium, and gold in this order.

As shown in FIG. 32, the lead 15 further has a displacement back surface 157, a displacement back surface 158, a connection surface 159, and a connection surface 150.

The displacement back surfaces 157, 158 face the opposite side of the main surface 111 (the second side z2 in the thickness direction z). The displacement back surfaces 157, 158 are located closer to the first side z1 of the thickness direction z than the back surfaces 152, 153, and thus closer to the main surface 151 than is the back surfaces 152, 153. The displacement back surface 157 is connected to the end surface 155 and is exposed from the sealing resin 4. The displacement back surface 158 is connected to the end surface 156 and is exposed from the sealing resin 4. The connection surface 159 is connected to the back surface 152 and the displacement back surface 157 and is exposed from the sealing resin 4. In this embodiment, the connection surface 159 is perpendicular to the back surface 152. The connection surface 150 is connected to the back surface 153 and the displacement back surface 158 and is exposed from the sealing resin 4. In this embodiment, the connection surface 150 is perpendicular to the back surface 153.

In the lead 15, the back surfaces 152, 153, the displacement back surfaces 157, 158, and the connection surfaces 159, 150 that are exposed from the sealing resin 4 are tin plated, for example. Instead of the tin plating, multiple metal plating may be employed, for example, with layers of nickel, palladium, and gold in this order.

As shown in FIG. 31, the lead 16 has displacement back surfaces 165, 166 and connection surfaces 167, 168.

The displacement back surfaces 165, 166 face the opposite side of the main surface 161 (the second side z2 in the thickness direction z). The displacement back surfaces 165, 166 are located closer to the first side z1 of the thickness direction z than the back surface 162, and thus closer to the main surface 161 than is the back surface 162. The displacement back surface 165 is connected to the end surface 163 and is exposed from the sealing resin 4. The displacement back surface 166 is connected to the end surface 164 and is exposed from the sealing resin 4. The connection surface 167 is connected to the back surface 162 and the displacement back surface 165 and is exposed from the sealing resin 4. In this embodiment, the connection surface 167 is perpendicular to the back surface 162. The connection surface 168 is connected to the back surface 162 and the displacement back surface 166 and is exposed from the sealing resin 4. In this embodiment, the connection surface 168 is perpendicular to the back surface 162.

In the lead 16, the back surface 162, the displacement back surface 165, 166, and the connection surfaces 167, 168, which are exposed from the sealing resin 4, are tin plated, for example. Instead of the tin plating, multiple metal plating may be employed, for example, with layers of nickel, palladium, and gold in this order.

As shown in FIG. 33, each lead 17 has a displacement back surface 174 and a connection surface 175.

The displacement back surface 174 faces the opposite side of the main surface 171 (the second side z2 in the thickness direction z). The displacement back surface 174 is located closer to the first side z1 of the thickness direction z than the back surface 172 and thus closer to the main surface 171 than is the back surface 172. The displacement back surface 174 is connected to the end surface 173 and is exposed from the sealing resin 4. The connection surface 175 is connected to the back surface 172 and the displacement back surface 174 and is exposed from the sealing resin 4. In this embodiment, the connection surface 175 is perpendicular to the back surface 172.

In each lead 17, the back surface 172, the displacement back surface 174, and the connection surface 175, which are exposed from the sealing resin 4, are tin plated, for example. Instead of the tin plating, multiple metal plating may be employed, for example, with layers of nickel, palladium, and gold in this order.

As shown in FIGS. 24, 25 and 34, each lead 19 has a displacement back surface 194 and a connection surface 195.

The displacement back surface 194 faces the opposite side of the main surface 191 (the second side z2 in the thickness direction z). The displacement back surface 194 is located closer to the first side z1 of the thickness direction z than the back surface 192 and thus closer to the main surface 191 than is the back surface 192. The displacement back surface 194 is connected to the end surface 193 and is exposed from the sealing resin 4. The connection surface 195 is connected to the back surface 192 and the displacement back surface 194 and is exposed from the sealing resin 4. In this embodiment, the connection surface 195 is perpendicular to the back surface 192.

In each lead 19, the back surface 192, the displacement back surface 194, and the connection surface 195, which are exposed from the sealing resin 4, are tin plated, for example. Instead of the tin plating, multiple metal plating may be employed, for example, with layers of nickel, palladium, and gold in this order.

The lead 20 has a displacement back surface 204 and a connection surface 205. The displacement back surface 204 faces the opposite side of the main surface 201 (the second side z2 in the thickness direction z). The displacement back surface 204 is located closer to the first side z1 of the thickness direction z than the back surface 202 and thus is closer to the main surface 201 than is the back surface 202. The displacement back surface 204 is connected to the end surface 203 and is exposed from the sealing resin 4. The connection surface 205 is connected to the back surface 202 and the displacement back surface 204 and is exposed from the sealing resin 4. In this embodiment, the connection surface 205 is perpendicular to the back surface 202.

In the lead 20, the back surface 202, the displacement back surface 204, and the connection surface 205, which are exposed from sealing resin 4, are tin plated, for example. Instead of the tin plating, multiple metal plating may be employed, for example, with layers of nickel, palladium, and gold in this order.

As shown in FIGS. 24, 25 and 34, each lead 21 has a displacement back surface 214 and a connection surface 215. The displacement back surface 214 faces the opposite side of the main surface 211 (the second side z2 in the thickness direction z). The displacement back surface 214 is located closer to the first side z1 of the thickness direction z than the back surface 212 and thus closer to the main surface 211 than is the back surface 212. The displacement back surface 214 is connected to the end surface 213 and is exposed from the sealing resin 4. The connection surface 215 is connected to the back surface 212 and the displacement back surface 214 and is exposed from the sealing resin 4. In this embodiment, the connection surface 215 is perpendicular to the back surface 212.

In each lead 21, the back surface 212, the displacement back surface 214, and the connection surface 215, which are exposed from the sealing resin 4, are tin plated, for example. Instead of the tin plating, multiple metal plating may be employed, for example, with layers of nickel, palladium, and gold in this order.

The lead 22 has a displacement back surface 224 and a connection surface 225. The displacement back surface 224 faces the opposite side of the main surface 221 (the second side z2 in the thickness direction z). The displacement back surface 224 is located closer to the first side z1 of the thickness direction z than the back surface 222 and thus closer to the main surface 221 than is the back surface 222. The displacement back surface 224 is connected to the end surface 223 and is exposed from the sealing resin 4. The connection surface 225 is connected to the back surface 222 and the displacement back surface 224 and is exposed from the sealing resin 4. In this embodiment, the connection surface 225 is perpendicular to the back surface 222.

In the lead 22, the back surface 222, the displacement back surface 224, and the connection surface 225, which are exposed from sealing resin 4, are tin plated, for example. Instead of the tin plating, multiple metal plating may be employed, for example, with layers of nickel, palladium, and gold in this order.

The lead 23 has a displacement back surface 234 and a connection surface 235. The displacement back surface 234 faces away from the main surface 231 (the second side z2 of the thickness direction z). The displacement back surface 234 is located closer to the first side z1 of the thickness direction z than the back surface 232 and thus closer to the main surface 231 than is the back surface 232. The displacement back surface 234 is connected to the end surface 233 and is exposed from the sealing resin 4. The connection surface 235 is connected to the back surface 232 and the displacement back surface 234 and is exposed from the sealing resin 4. In this embodiment, the connection surface 235 is perpendicular to the back surface 232.

In the lead 23, the back surface 232, the displacement back surface 234, and the connection surface 235, which are exposed from the sealing resin 4, are tin plated, for example. Instead of the tin plating, multiple metal plating may be employed, for example, with layers of nickel, palladium, and gold in this order.

Each lead 25 has a displacement back surface 255 and a connection surface 256. The displacement back surface 255 faces the opposite side of the main surface 251 (the second side z2 in the thickness direction z). The displacement back surface 255 is located closer to the first side z1 of the thickness direction z than the back surface 252 and thus closer to the main surface 251 than is the back surface 252. The displacement back surface 255 is connected to the end surfaces 253 and 254 and is exposed from the sealing resin 4. The connection surface 256 is connected to the back surface 252 and the displacement back surface 255 and is exposed from the sealing resin 4. In this embodiment, the connection surface 256 is perpendicular to the back surface 252.

Each lead 25 is located at a corner of sealing resin 4 as viewed in the thickness direction z. The back surface 252 of each lead 25 is fan-shaped and the corresponding corner of the sealing resin 4 is arc-shaped. Thus, the connection surface 256 connecting to the arc-shaped back surface 252 is curved and convex outwardly as viewed in the thickness direction z.

In this embodiment, the displacement back surface 255 and connection surface 256 of each lead 25 are formed by laser irradiation, as shown in the manufacturing method described below. The laser irradiation is performed by outputting pulses that periodically repeat on and off. The repeated on-off output of the pulses forms unevenness in the surface as a trace of the laser irradiation. The unevenness extends in a direction perpendicular to the scanning direction of the laser. Thus, as shown in FIG. 35, the displacement back surface 255 is formed with a plurality of convexities 291 spaced apart at certain intervals, with each convexity extending in a direction perpendicular to the thickness direction z. It should be noted that such a configuration may also hold for the leads 11-23.

In each lead 25, the back surface 252, the displacement back surface 255, and the connection surface 256, which are exposed from the sealing resin 4, are tin plated, for example. Instead of the tin plating, a plurality of metal plating may be employed, for example, nickel, palladium, and gold layered in this order.

The lead 18 has displacement back surfaces 185a, 185b, 185c and connection surfaces 186a, 186b, 186c. The displacement back surfaces 185a, 185b, and 185c face the opposite side of the main surface 181 (the second side z2 in the thickness direction z). The displacement back surfaces 185a, 185b, 185c are located closer to the first side z1 of the thickness direction z than the back surfaces 182a, 182b, 182c, and thus closer to the main surface 181 than are the back surfaces 182a, 182b, 182c. The displacement back surface 185a is connected to the end surface 183a and is exposed from the sealing resin 4. The displacement back surface 185b is connected to the end surfaces 183b and 184b and is exposed from the sealing resin 4. The displacement back surface 185c is connected to the end surface 183c and is exposed from the sealing resin 4. The connection surface 186a is connected to the back surface 182a and the displacement back surface 185a and is exposed from the sealing resin 4. In this embodiment, the connection surface 186a is perpendicular to the back surface 182a. The connection surface 186c is connected to the back surface 182c and the displacement back surface 185c and is exposed from the sealing resin 4. In this embodiment, the connection surface 186c is perpendicular to the back surface 182c. The connection surface 186b is connected to the back surface 182b and the displacement back surface 185b and is exposed from the sealing resin 4. In this embodiment, the connection surface 186b is perpendicular to the back surface 182b.

The lead 18 is located at a corner of the sealing resin 4 as viewed in the thickness direction z. The back surface 182b of the lead 18 is fan-shaped, and the corresponding corner of the sealing resin 4 is arc-shaped. Thus, the connection surface 186b, which connects to the arc-shaped back surface 182b, is curved and convex outwardly as viewed in the thickness direction z.

In the lead 18, the back surfaces 182a, 182b, 182c, the displacement back surfaces 185a, 185b, 185c, and the connection surfaces 186a, 186b, 186c that are exposed from sealing resin 4 are tin plated, for example. Instead of the tin plating, multiple metal plating may be employed, for example, with layers of nickel, palladium, and gold in this order.

The sealing resin 4 has a displacement bottom surface 44 and a connection surface 45, as shown in FIGS. 26 through 29 and 35. The displacement bottom surface 44 faces the opposite side of the top surface 41 (the second side z2 of the thickness direction z). The displacement bottom surface 44 is located closer to the first side z1 of the thickness direction z than the bottom surface 42 and closer to the top surface 41 than is the bottom surface 42. The displacement bottom surface 44 is connected to the first side surface 431, the second side surface 432, the third side surface 433, and the fourth side surface 434, and surrounds the bottom surface 42 as viewed in thickness direction z. As shown in FIG. 25, the following several surfaces are exposed from the displacement bottom surface 44 and these exposed surfaces are flush with the displacement bottom surface 44: the displacement back surface 116 of each lead 11-14; the displacement back surfaces 157, 158 of the lead 15; the displacement back surfaces 165, 166 of the lead 16; the displacement back surface 174 of each lead 17; the displacement back surfaces 185a, 185b, 185c of the lead 18; the displacement back surface 194 of each lead 19; the 204 displacement back surface of the lead 20; the displacement back surface 214 of each lead 21; the displacement back surface 224 of the lead 22; the displacement back surface 234 of the lead 23; and the displacement back surface 255 of each lead 25.

The connection surface 45 is connected to the bottom surface 42 and the displacement bottom surface 44 and is perpendicular to the bottom surface 42. As shown in FIGS. 25 through 29, the following surfaces are exposed from the connection surface 45: the connection surface 117 of each leads 11-14; the connection surface 117 of each leads 11-14; the connection surfaces 159, 150 of the lead 15; the connection surfaces 167, 168 of the lead 16; the connection surface 175 of the lead 17; the connection surfaces 186a, 186b, 186c of the lead 18; the connection surface 195 of each lead 19; the connection surface 205 of the lead 20; the connection surface 215 of each lead 21; the connection surface 225 of the lead 22; the connection surface 235 of the lead 23; and the connection surface 256 of each lead 25.

In this embodiment, the displacement bottom surface 44 and the connection surface 45 are formed by irradiating a laser, as shown in the manufacturing method described below. Thus, as shown in FIG. 35, the displacement bottom surface 44 is formed with a plurality of convexities 48 extending perpendicularly to the thickness direction z. A plurality of convexities 49 extending in the thickness direction z are formed on the connection surface 45.

In this embodiment, the rectangular semiconductor element 3 is arranged parallel to the rectangular sealing resin 4, as viewed in the thickness direction. As shown in FIGS. 23 and 24, the element side surfaces 301 and 302 are spaced apart from each other in the first direction x and face away from each other. The element side surface 301 faces the x1 side of the first direction x. The element side surface 302 faces the x2 side of the first direction x. The element side surfaces 303 and 304 are spaced apart from each other in the second direction y and face away from each other. The element side surface 303 faces the y1 side of the second direction y. The element side surface 304 faces the y2 side of the second direction y.

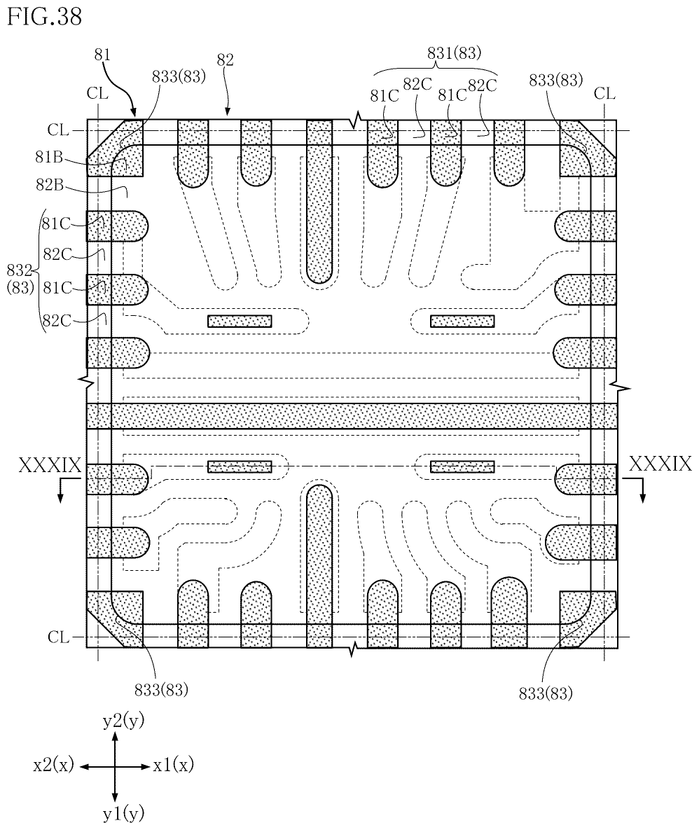

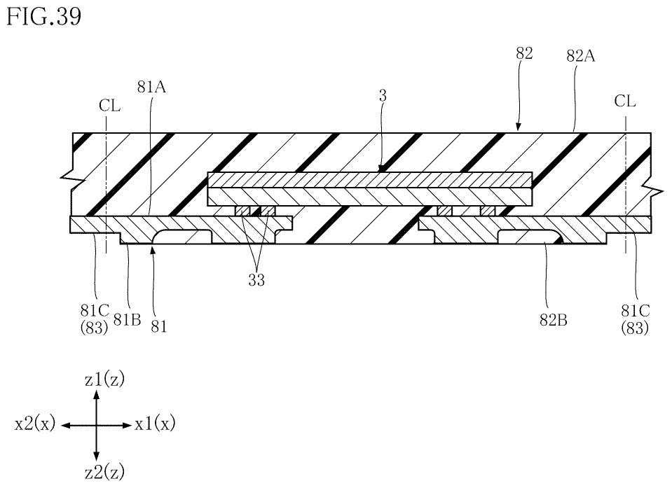

An example of a manufacturing method for the semiconductor device A50 is described below with reference to FIGS. 36 through 39. FIGS. 36 and 38 are bottom views showing a process of the manufacturing method of the semiconductor device A50, corresponding to FIG. 25. FIG. 37 is a cross-sectional view along the XXXVII-XXXVII line of FIG. 36, corresponding to FIG. 30. FIG. 39 is a cross-sectional view along the XXXIX-XXXIX line of FIG. 38, corresponding to FIG. 30.

First, a lead frame 81 is prepared. The lead frame 81 is a plate-shaped member to be processed to have the respective leads 11-25. The base material of the lead frame 81 is Cu in this embodiment. The lead frame 81 may be produced by etching a metal plate or by punching a metal plate. The lead frame 81 includes many parts or portions to be included within the semiconductor device A50. Further, the lead frame 81 also includes portions to be an outer frame (not shown) that does not constitute the semiconductor device A5. The lead frame 81 has a main surface 81A facing the first side z1 in the thickness direction z and a back surface 81B facing the second side z2. Then, a semiconductor element 3 is mounted on the main surface 81A of the lead frame 81 (element bonding process). In this step, the element main surface 305 is placed so as to face the lead frame 81, and each of the electrodes 33, 34 is conductively bonded to a predetermined part on the main surface 81A of the lead frame 81. Then, a sealing resin 4 is formed in a manner covering predetermined parts of the lead frame 81 and the semiconductor element 3 (resin forming process). The resulting sealing resin 82 has a top surface 82A facing the first side z1 in the thickness direction z and a bottom surface 82B facing the second side z2. Thus, as shown in FIGS. 36 and 37, the lead frame 81 has the semiconductor element 3 mounted thereon and has most portions thereof covered with the sealing resin 82. Several portions of the back surface 81B of the lead frame 81 (the portions corresponding to the back surfaces of the leads 11-25) are exposed from the bottom surface 82B of the sealing resin 82.

Next, as shown in FIGS. 38 and 39, a groove(s) 83 is formed (groove formation process). The groove 83 is formed so as to extend, as viewed in the thickness direction z, across the lead frame 81 and the sealing resin 82, thereby having a generally rectangular frame-like form, as viewed in the thickness direction z (see FIG. 38). In this embodiment, the groove 83 includes a plurality of grooves 81C formed in the lead frame 81 and a plurality of grooves 82C formed in the sealing resin 82. Each groove 81C is recessed from the back surface 81B of the lead frame 81 to an intermediate portion thereof in the first side z1 of the thickness direction z. Each groove 82C is recessed from the bottom 82B of the sealing resin 82 to an intermediate portion thereof in the first side z1 of the thickness direction z. The bottom surfaces of the grooves 81C and grooves 82C are flush with each other. In this embodiment, the groove 83 includes two (a plurality of) grooves 831 extending in the first direction x, two (a plurality of) grooves 832 extending in the second direction y, and four (a plurality of) connection surfaces 833. Each connection surface 833 is located at the intersection of corresponding grooves 831 and 832 and connects those grooves. The connection surfaces 833 are located on the portions of the lead frame 81 that later become the lead 18 and the leads 25. Each connection surface 833 is a curved surface as viewed in the thickness direction z and later becomes the connection surface 186b of a lead 18 or the connection surface 256 of a lead 25. Among the groove 83, the bottoms of the grooves 81C become the displacement back surfaces of the leads 11-25, and the bottoms of the grooves 82C become the displacement back surfaces of the sealing resin 4. Among the groove 83, the side surface of the groove 81C becomes the connection surface of each lead 11-25, and the side surface of the groove 82C becomes the connection surface 45 of the sealing resin 4.

In this embodiment, the groove 83 is formed by irradiating a laser in the groove formation process. However, the half-cut dicing process, which uses blade cutting, can only form the groove 83 in a straight line and thus cannot form the connection surface 833 noted above. In the embodiment, since the groove 83 is formed by laser irradiation, the curved connection surface 833, as viewed in the thickness direction z, can be properly produced. The laser irradiation is performed by a pulse output that periodically repeats on and off. Hence, a certain pattern of unevenness is formed as a mark where the laser is irradiated. The unevenness extends in a direction perpendicular to the scanning direction of the laser. Thus, a plurality of convexities extending in the direction perpendicular to the thickness direction z and the laser scanning direction are formed on the bottom surface of the groove 83 (see the convexity 291 on the displacement back surface 255 and the convexity 48 on the displacement bottom surface 44 in FIG. 35). Likewise, a plurality of convexities extending in the thickness direction z are formed on the side surface of the groove 83 (see the convexity 292 of the connection surface 256 and the convexity 49 of the connection surface 45 in FIG. 35). The method of forming the groove 83 in the groove formation process is not limited to laser irradiation. For example, the groove 83 may be formed by other methods, such as by etching.

Next, plating is applied to the back surface 81B of the lead frame 81 exposed from the bottom surface 82B of the sealing resin 82 and to the surface of the groove 81C exposed from the groove 82C. In this embodiment, tin plating may be employed, for example.

Next, fragmentation is performed by cutting along the cutting lines CL shown in FIGS. 38 and 39 (cutting process). The cutting process may be performed by a full-cut dicing process with a cutting blade. In this embodiment, the thickness dimension of the blade is smaller than the width dimension of the groove 83 (the dimension in the direction perpendicular to the thickness direction z and the direction in which the cut line CL extends). Specifically, first, a cut is made to a predetermined removal area extending along the groove 831 (an area outside of the cut line CL in FIGS. 38 and 39), where the removal area is a region that is narrower in width (dimension in the second direction y) than groove 831 as viewed in the thickness direction z, and the entirety of which overlaps with the groove 831. In this cutting, the entire portions of the lead frame 81 and the sealing resin 82 that vertically correspond to the removal areal are removed. As a result, the lead frame 81 and the sealing resin 82 are formed with a cut plane facing in the second direction y. Then, another cut is made to another predetermined removal area extending along the groove 832 (an area outside of the cut line CL in FIGS. 38 and 39), where the removal area is a region that is narrower in width (dimension in the first direction x) than the groove 832 as viewed in the thickness direction z, and the entirety of which overlaps with the groove 832. In this cutting, the entire portions of the lead frame 81 and the sealing resin 82 that vertically correspond to the removal areal are removed. As a result, the lead frame 81 and the sealing resin 82 are formed with another cut plane facing in the first direction x. The cut planes of the lead frame 81 become the end faces of the respective leads 11-25, while the cut planes of the sealing resin 82 become the first side surface 431, the second side surface 432, the third side surface 433, and the fourth side surface 434. The cutting method used for the cutting process is not limited to the blade cutting explained above. For example, the cutting may be performed by other methods, such as laser irradiation.

By the processes described above, the semiconductor device A50 is manufactured.

Next, effects of the semiconductor device A50 will be described.

According to this embodiment, the leads 25 and 18 are located at the corners of the sealing resin 4, as viewed in the thickness direction z. In each lead 25, the back surface 252 is arc-shaped (fan-shaped) on the corner side of the corresponding sealing resin 4. Thus, the connection surface 256 connected to the back surface 252 is curved and convex outwardly as viewed in the thickness direction z. Likewise, as viewed in the thickness direction z, the back surface 182b of lead 18 is arc-shaped (fan-shaped) on the corner side of the sealing resin 4. Thus, the connection surface 186b connected to the back surface 182b is also curved and convex outward, as viewed in the thickness direction z. Accordingly, when the semiconductor device A50 is mounted on a circuit board via solder, it is possible to properly distribute the stresses to be concentrated in the solder applied to the back surfaces 252, 182b. Thus, with the semiconductor device A50, it is possible to improve mounting reliability, compared to the case where the back surfaces 252, 182b have other shapes than the one of the present disclosure.

In this embodiment, when the semiconductor device A50 is manufactured, the groove 83 is formed by irradiating a laser in the groove formation process. Thus, regarding the groove 83, a connection surface 833, which is curved as viewed in the thickness direction z, can be properly formed. Accordingly, in the semiconductor device A50, the formation of the connection surfaces 255 of the leads 25 and the connection surface 186b of the lead 18 can be easily achieved.

### First Variation of Fifth Embodiment

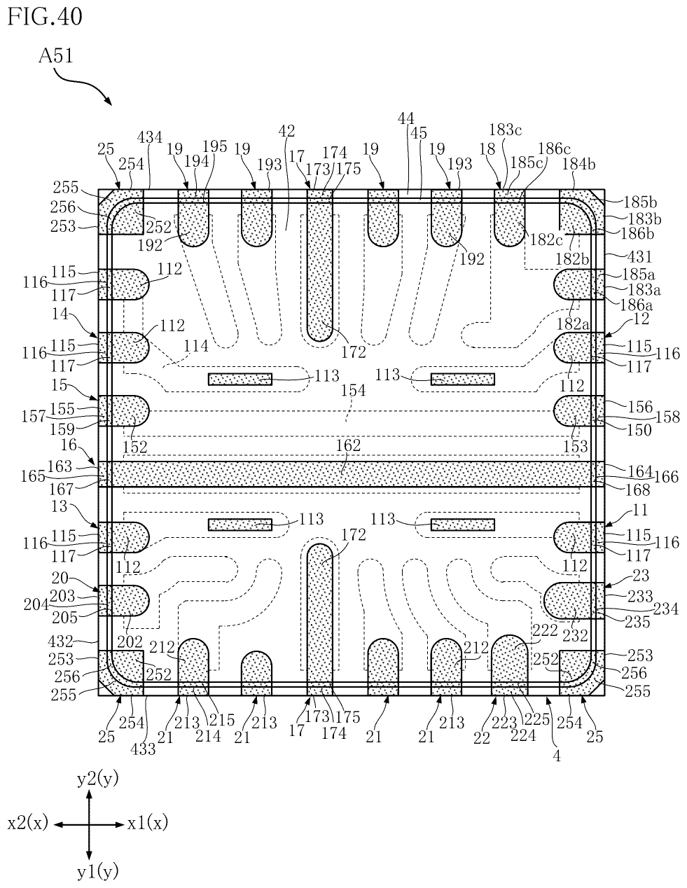

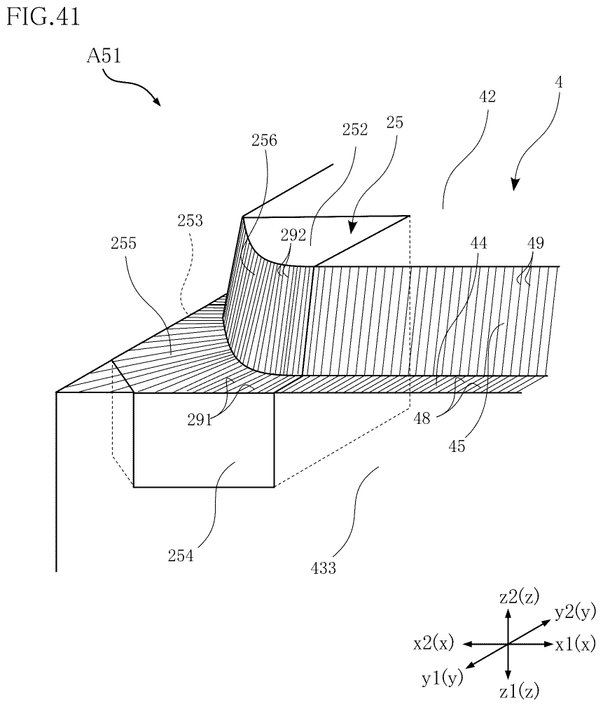

FIGS. 40 and 41 show a semiconductor device A51 according to a first variation of the fifth embodiment. FIG. 40 is a bottom view of the semiconductor device A51, corresponding to FIG. 25. FIG. 41 is an enlarged partial view of the semiconductor device A51, corresponding to FIG. 35. In FIG. 40 and the subsequent drawings, elements identical or similar to those of the above semiconductor device A50 are indicated by the same references as in the above embodiment, and explanations may be omitted.

In the semiconductor device A51, the connection surfaces of the leads 11-25 and the connection surfaces 45 of the sealing resin 4 are inclined with respect to the thickness direction z. For example. as shown in FIG. 41, the connection surface 256 of each lead 25 is inclined with respect to the thickness direction z. Likewise, the following connection surfaces are inclined with respect to the thickness direction z: the connection surfaces 117 of the leads 11-14; the connection surfaces 159, 150 of the lead 15; the connection surfaces 167, 168 of the lead 16; the connection surface 175 of each lead 17; the connection surfaces 186a, 186b, 186c of the lead 18; the connection surface 195 of each lead 19; the connection surface 205 of the lead 20; the connection surface 215 of each lead 21; the connection surface 225 of the lead 22; and the connection surface 235 of the lead 23. Regarding the leads 25, 18 located at the corners of the, sealing resin 4, the inclined arrangement of the connection surfaces 256, 186b being inclined with respect to the thickness direction z is more advantageous than the parallel arrangement of the connection surfaces 256, 186b being parallel to the thickness direction z (in other words, perpendicular to the bottom surface 42 of the sealing resin 4) in that it is possible to properly disperse the stress to be concentrated in the solder applied to the back surfaces 252, 182b.

### Second Variation of Fifth Embodiment

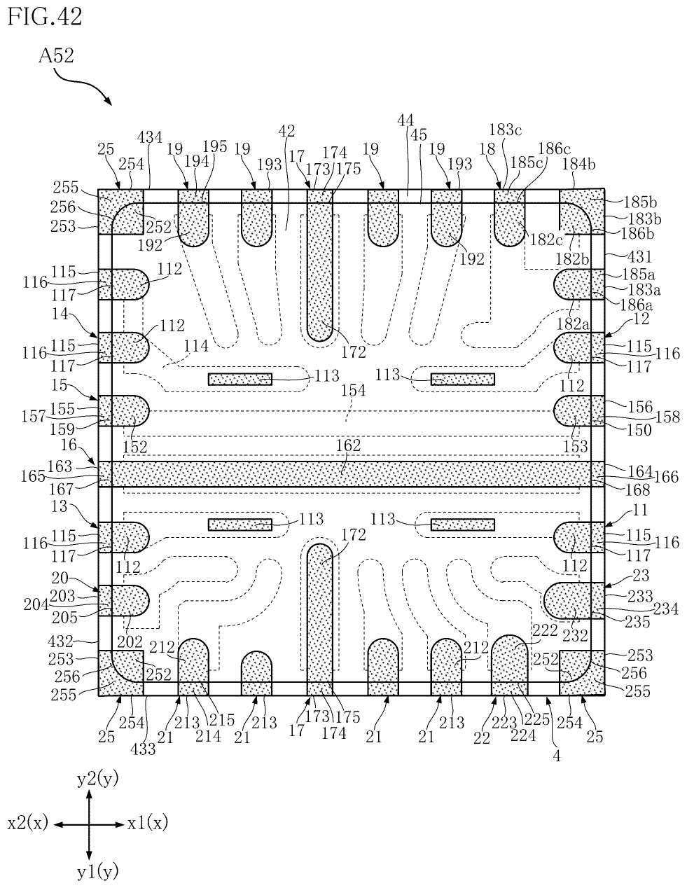

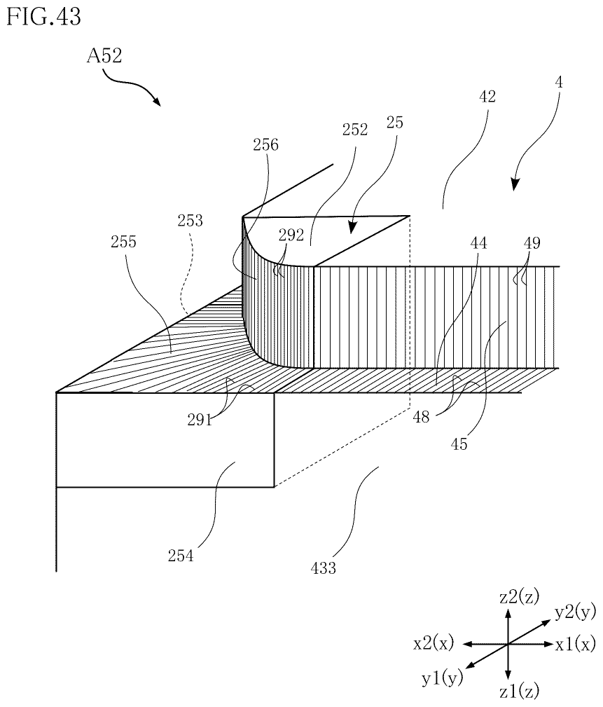

FIGS. 42 and 43 show a semiconductor device A52 according to a second variation of the fifth embodiment. FIG. 42 is a bottom view of the semiconductor device A52, corresponding to FIG. 25. FIG. 43 is an enlarged partial view of the semiconductor device A52, corresponding to FIG. 35.

In the semiconductor device A52, the shapes of the leads 25 and the lead 18 are different from those of the semiconductor device A51. As shown in FIG. 43, the end faces 253, 254 of the lead 25 are connected to each other. Likewise, the end faces 183b, 184b of the lead 18 are connected to each other (see FIG. 42).

### Third Variation of Fifth Embodiment

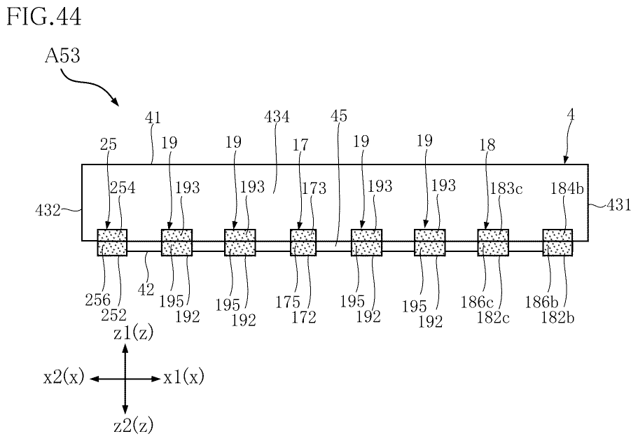

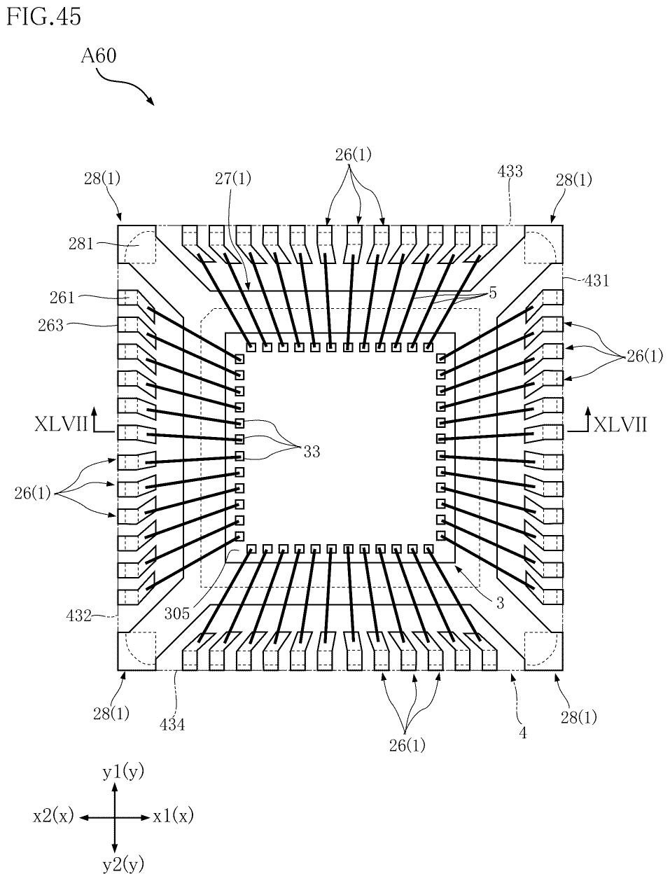

FIG. 44 shows a semiconductor device A53 according to a third variation of the fifth embodiment. FIG. 44 is a front view of the semiconductor device A53, corresponding to FIG. 26.

In the semiconductor device A53, the back surface of each lead 11-25 is not flush with the bottom surface 42 of the sealing resin 4. For example, as shown in FIG. 44, the back surface 172 of the lead 17, the back surface 192 of each lead 19, the back surfaces 182b, 182c of the lead 18, and the back surface 252 of the lead 25 are not flush with the bottom surface 42, but protrude from the bottom surface 42 to the second side z2 of the thickness direction z. Likewise, the back surfaces 112, 113 of each lead 11-14, the bac surfaces 152, 153 of the lead 15, the back surface 162 of the lead 16, the back surface 182a of the lead 18, the back surface 202 of the lead 20, the back surface 212 of each lead 21, the back surface 222 of the lead 22, and the back surface 232 of the lead 23 are not flush with the bottom surface 42, but protrude from the bottom surface 42 to the second side z2 of the thickness direction z. As understood from the third variation, it suffices that the back surface of each lead 11-25 is exposed from the sealing resin 4, and the back surface may or may not be flush with the bottom surface 42.

### Sixth Embodiment

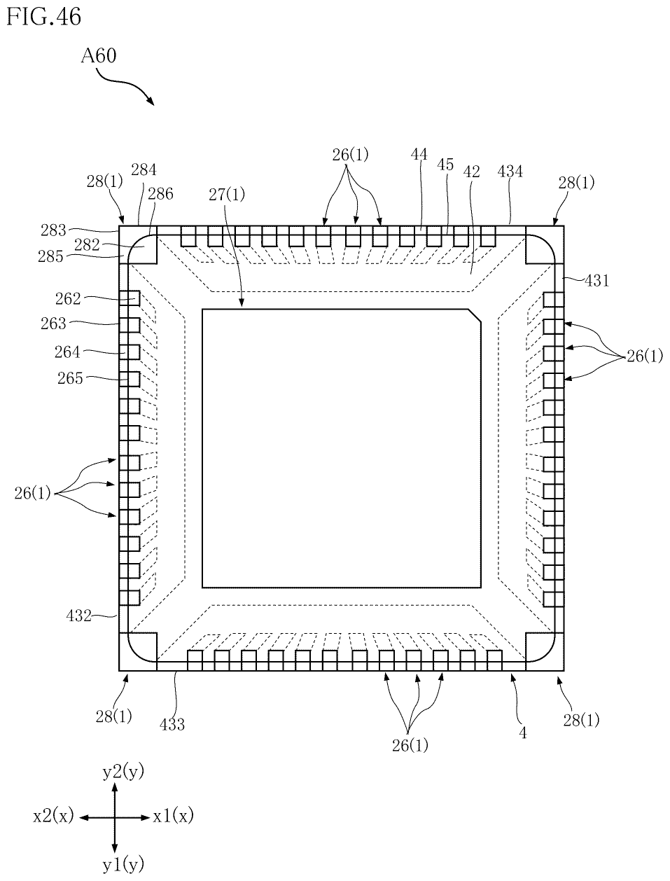

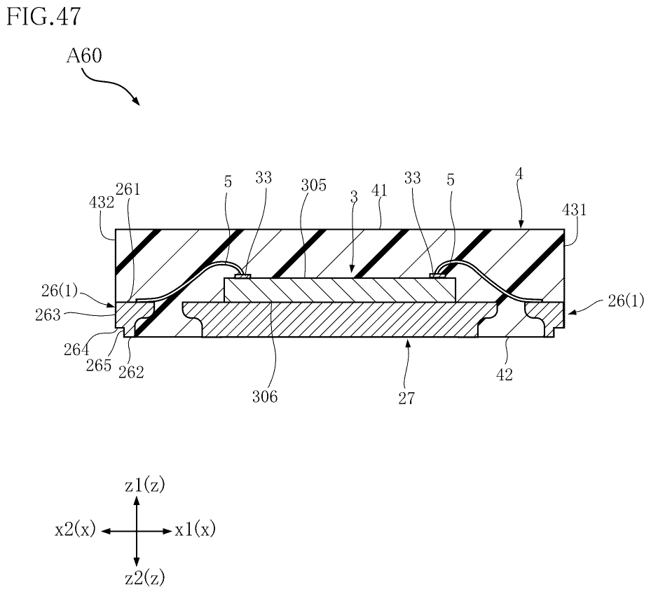

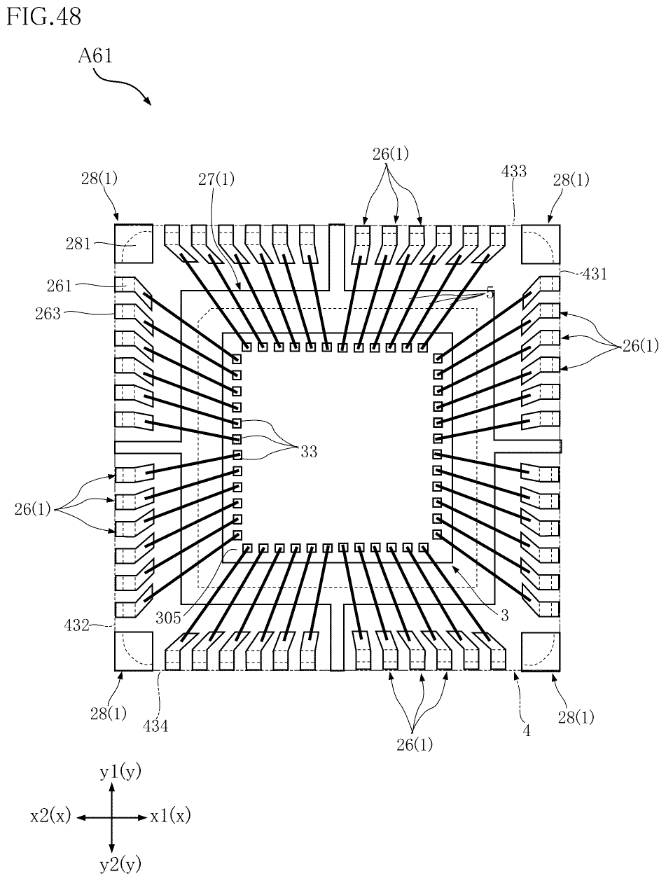

FIGS. 45-47 show a semiconductor device A60 according to a sixth embodiment of the present disclosure. FIG. 45 is a plan view of the semiconductor device A60, corresponding to FIG. 23. FIG. 46 is a bottom view of the semiconductor device A60, corresponding to FIG. 25. FIG. 47 is a cross-sectional view along the XLVII-XLVII line of FIG. 45, corresponding to, for example, FIG. 30. FIG. 45 shows the sealing resin 4 as being transparent for convenience of understanding. The semiconductor device A60 differs from that of the fifth embodiment in the orientation of the semiconductor element 3 in the thickness direction z. The configurations and operation of the other parts of this embodiment may be the same as those of the fifth embodiment. In this embodiment, configurations of the fifth embodiment and its variation may be combined as appropriate.

In the semiconductor device A60, the conductive member 1 includes a lead 27, four leads 28, and a plurality of leads 26. The lead 27 includes a die pad and is located in the center of the semiconductor device A60 as viewed in the thickness direction z. The semiconductor element 3 is mounted on the lead 27. In this embodiment, thee semiconductor element 3 is bonded to the die pad (lead 27) with the element main surface 305 facing to the first side z1 of the thickness direction z.

As viewed in the thickness direction z, the four leads 28 are located in the four corners of the semiconductor device A60, respectively. Each lead 28 is connected to the lead 27 and includes a main surface 281, a back surface 282, end faces 283, 284, a displacement back surface 285, and a connection surface 286. The main surface 281 faces the first side z1 of the thickness direction z and is covered by the sealing resin 4. The back surface 282 faces the opposite side of the main surface 281 (the second side z2 in the thickness direction z) and is exposed from the sealing resin 4. The end face 283 is connected to the main surface 281 and faces in the first direction x. The other end face 283 is connected to the main surface 281 and faces in the second direction y. The end faces 283, 284 are exposed from the sealing resin 4.

The displacement back surface 285 faces the opposite side of the main surface 281 (the second side z2 in the thickness direction z). The displacement back surface 285 is located closer to the first side z1 of the thickness direction z than the back surface 282 and thus closer to the main surface 281 than is the back surface 282. The displacement back surface 285 is connected to the end faces 283, 284 and is exposed from the sealing resin 4. The connection surface 286 is connected to the back surface 282 and the displacement back surface 285 and is exposed from the sealing resin 4. In this embodiment, the connection surface 286 is perpendicular to the back surface 282.

The four leads 28 are located in the corners of sealing resin 4, respectively, as viewed in the thickness direction z. The back surface 282 of each lead 28 is fan-shaped, and the corresponding corner of the sealing resin 4 is arc-shaped. Thus, the connection surface 286 connected to the arc-shaped portion of the back surface 282 is curved and convex outward as viewed in the thickness direction z. In this embodiment, the displacement back surface 285 and the connection surface 286 of the four 28 leads may also be formed by irradiating a laser. Thus, the displacement back surface 285 of lead 28 is formed with a plurality of convexities 291 extending in a direction perpendicular to the thickness direction z, as with the displacement back surface 255 of the lead 25 in the fifth embodiment. The connection surface 286 is formed with a plurality of convexities 292 extending in the thickness direction z.

In each lead 28, the back surface 282, the displacement back surface 285, and the connection surface 286, which are exposed from the sealing resin 4, are tin plated, for example. Instead of the tin plating, multiple metal plating may be employed, for example, with layers of nickel, palladium, and gold in this order.

The plurality of leads 26 are distributed along the two edges of the semiconductor device A60 spaced in the first direction x and along the two edges spaced in the second direction y, so that the respective groups along the four edges includes multiple leads. Each electrode 33 of the semiconductor element 3 is conductively connected by a wire 5 to one of the plurality of leads 26. Each lead 26 has a main surface 261, a back surface 262, an end face 263, a displacement back surface 264, and a connection surface 265. The main surface 261 faces the first side z1 of the thickness direction z, and is covered by the sealing resin 4. The back surface 262 faces the opposite side of the main surface 261 (the second side z2 in the thickness direction z), and is exposed from the sealing resin 4. The end face 263 is connected to the main face 261 and faces outward. The end face 263 is exposed from the sealing resin 4.

The displacement back surface 264 faces the opposite side of the main surface 261 (the second side z2 in the thickness direction z). The displacement back surface 264 is located closer to the first side z1 of the thickness direction z than the back surface 262 and thus closer to the main surface 261 than is the back surface 262. The displacement back surface 264 is connected to the end face 263 and is exposed from the sealing resin 4. The connection surface 265 is connected to the back surface 262 and the displacement back surface 264 and is exposed from the sealing resin 4. In this embodiment, the connection surface 265 is perpendicular to the back surface 262.

In each lead 26, the back surface 262, the displacement back surface 264, and the connection surface 265, which are exposed from the sealing resin 4, are tin plated, for example. Instead of the tin plating, multiple metal plating may be employed, for example, with layers of nickel, palladium, and gold in this order. The main surface 261 may be silver plated, for example, for facilitating the adhesion of a wire 5.

The four leads 28 are located in the corners of the sealing resin 4, respectively, as viewed in the thickness direction z. In each lead 28, the back surface 282 is arc-shaped (fan-shaped) on the corner side of the sealing resin 4. Thus, the connection surface 286 connected to the back surface 282 is curved and convex outwardly as viewed in the thickness direction z. This allows the semiconductor device A60 to disperse the stress to be concentrated on the solder bonded to the back surface 282. Therefore, the semiconductor device A60 can improve mounting reliability compared to the case where the back surface 282 is not arc-shaped, e.g., rectangular. The semiconductor device A60 (or the method for manufacturing the semiconductor device A60) may have a common configuration with the semiconductor device A50 (or the method for manufacturing the semiconductor device A50), thereby achieving equivalent effects.

### First Variation of Sixth Embodiment

FIG. 48 shows a semiconductor device A61 for the first variation of the sixth embodiment. FIG. 48 is a plan view of the semiconductor device A61, corresponding to FIG. 23. FIG. 48 shows the sealing resin 4 as being transparent for convenience of understanding.

In the semiconductor device A61, the lead 27 is not connected to the leads 28 located in the four corners of the semiconductor device A61. Instead, the lead 27 is fixed by suspension leads exposed from the first side surface 431, the second side surface 432, the third side surface 433, and the fourth side surface 434 of the sealing resin 4.

In the fifth and sixth embodiments, the package type of the semiconductor device A50, A60 (A51, A52, A53, A61) is a QFN, but the present disclosure is not limited to this. For instance, the package type of a semiconductor device of the present disclosure may be a DFN (Dual Flat Non-Lead Package). Further, instead of these two types, other package types may be applicable by the present disclosure.

In the first embodiment to the six embodiment, the first side surface to the fourth side surface 431-434 of the sealing resin 4 are perpendicular (or substantially perpendicular) to the top surface 41 and the bottom surface 42. The present disclosure is not limited to this. For instance, at leas one of the first side surface to the fourth side surface 431-434 may not be perpendicular to the top surface 41 and/or the bottom surface 42. Further, at leas one of the first side surface to the fourth side surface 431-434 may have two or more divided sections (each may be flat, for example) in the thickness direction z, and one of the divided sections may not be perpendicular to the top surface 41 and/or the bottom surface 42.

In the first embodiment to the sixth embodiment, the element side surfaces 301-304 of the semiconductor element 3 are perpendicular (or substantially perpendicular) to the element main surface 305 and the element back surface 306. The present disclosure is not limited to this. For instance, at least one of the element sides 301-304 may not be perpendicular to the element main surface 305 and/or the element back surface 306.

The semiconductor devices and manufacturing methods of such semiconductor devices according to the present disclosure are not limited to the embodiments described above. According to the present disclosure, the configurations of the elements/components/parts etc. of the semiconductor device and the processes of the manufacturing method can be modified in various ways.

The present disclosure includes the embodiments presented in the following clauses.

Clause A1. A semiconductor device comprising:
a semiconductor element (3) including an element main surface (305) facing in a thickness direction (z) and being provided with an electrode (33); and
a sealing resin (4) including a resin top surface (41) facing a first side (z1) of the thickness direction, the sealing resin covering the semiconductor element, wherein
the element main surface and the resin top surface are rectangular, and
a first edge (305a) of the element main surface is inclined with respect to a second edge (41a) of the resin top surface, as viewed in the thickness direction.

Clause A2. The semiconductor device according to clause A1, wherein an inclination angle of the first edge relative to the second edge is greater than 0° and less than 45° as viewed in the thickness direction.

Clause A3. The semiconductor device according to clause A2, wherein the inclination angle is not less than 5° and not greater than 45°.

Clause A4. The semiconductor device according to clause A3, wherein the inclination angle is 45°.

Clause A5. The semiconductor device according to any one of clauses A1 to A4, wherein the resin top surface has four corners including a first corner (46) located closest to the first edge of the four corners, and
as viewed in the thickness direction, a distance (D1) between the first edge and the first corner is not less than 25% of a length (D2) of a diagonal of the resin top surface.

Clause A6. The semiconductor device according to any one of clauses A1 to A5, further comprising a conductive member (1) electrically connected to the semiconductor element, wherein
the semiconductor element is disposed such that the element main surface faces a second side (z2) of the thickness direction, and
the electrode is electrically connected to the conductive member.

Clause A7. The semiconductor device according to any one of clauses Al to A5, further comprising: a conductive member electrically connected to the semiconductor element; and
a connection member (5) electrically connecting the semiconductor element and the conductive member to each other, wherein
the semiconductor element is disposed such that the element main surface faces the first side of the thickness direction, and
the connection member is electrically connected to the electrode and the conductive member.

Clause A8. The semiconductor device according to clause A6 or A7, wherein the conductive member includes a plurality of leads (11-25) each having a lead main surface facing the first side of the thickness direction and a lead back surface facing the second side of the thickness direction.

Clause A9. The semiconductor device according to clause A8, wherein the sealing resin includes a resin bottom surface (42) facing the second side of the thickness direction, and
the lead back surfaces of the plurality of leads are exposed from the resin bottom surface.

Clause A10. The semiconductor device according to clause A9, wherein
the plurality of leads includes first leads (11, 22, 17) and second leads (19, 17),
the lead back surfaces of the first leads are arranged along a first direction (x) parallel to the second edge,
the lead back surfaces of the second leads are spaced apart from the lead back surfaces of the first leads in a second direction (y) perpendicular to the thickness direction and the first direction, while also being arranged along the first direction.

Clause A11. The semiconductor device according to clause A10, wherein the plurality of leads further include third leads (11, 12, 15, 16, 23), and
the lead back surfaces of the third leads are disposed along the second direction.

Clause A12. The semiconductor device according to clause A10 or A11, wherein the plurality of leads include a fourth lead (25), and
the fourth lead has a first end face (253) facing in the first direction and exposed from the sealing resin, and a second end face (254) facing in the second direction and exposed from the sealing resin, the fourth lead being not electrically connected to the semiconductor element.

Clause A13. The semiconductor device according to any one of clauses A10 to A12, wherein the plurality of leads include a fifth lead (18), and
the fifth lead has a third end face (186) facing in the first direction and exposed from the sealing resin, and a fourth end face (187) facing in the second direction and exposed from the sealing resin, the fifth lead being electrically connected to the semiconductor element.

Clause A14. (second embodiment, FIG. 15) The semiconductor device according to any one of clauses A8 to A13, wherein the plurality of leads includes a die pad (271) on which the semiconductor element is mounted,
the die pad has a die pad main surface (271a) facing the first side of the thickness direction,
the die pad main surface is rectangular, and
as viewed in the thickness direction, the die pad main surface has a third edge (271b) is substantially parallel to the first edge.

Clause A15. (first variation of second embodiment, FIG. 17) The semiconductor device according to any one of clauses A8 to A13, wherein the plurality of leads include a die pad on which the semiconductor element is mounted,
the die pad has a die pad main surface facing the first side of the thickness direction,
the die pad main surface is rectangular, and
as viewed in the thickness direction, the die pad main surface has a third edge is substantially parallel to the second edge.

Clause A16. (fourth embodiment, FIGS. 20 and 21) The semiconductor device according to clause A6 or A7, further comprising a base member (61) having a base member main surface (61a) facing in the first side of the thickness direction and a base member back surface (61b) facing in the second side of the thickness direction,
wherein the conductive member includes a conductive part (63) disposed in a through-hole extending through the base member in the thickness direction.

Clause B1. (fifth embodiment) A semiconductor device comprising:
a semiconductor element (3) having an element main surface (305) facing in a thickness direction (z) with an electrode (33) disposed on the element main surface;
a conductive member (1) electrically connected to the semiconductor element; and
a sealing resin (4) having a resin top surface (41) facing a first side of the thickness direction and a resin bottom surface (42) facing a second side (z2) of the thickness direction, the sealing resin covering a portion of the conductive member and the semiconductor element, wherein
the conductive member includes a first lead (25) located in a corner of the sealing resin as viewed in the thickness direction,
the first lead includes a first bottom surface (252) facing the second side of the thickness direction, a second bottom surface (255) facing the second side of the thickness direction and closer to the first side of the thickness direction than is the first bottom surface, and a connection surface (256) connected to the first bottom surface and the second bottom surface, and
the connection surface is curved as viewed in the thickness direction.

Clause B2. The semiconductor device according to clause B1, wherein the connection surface is convex outwardly as viewed in the thickness direction.

Clause B3. The semiconductor device according to clause B1 or B2, wherein the first bottom surface, the second bottom surface and the connection surface are exposed from the sealing resin, and
the first bottom surface is flush with the resin bottom surface.

Clause B4. The semiconductor device according to any one of clauses B1 to B3, wherein the connection surface is perpendicular to the first bottom surface.

Clause B5. The semiconductor device according to any one of clauses B1 to B3, wherein the connection surface is inclined with respect to the thickness direction.

Clause B6, The semiconductor device according to any one of clauses B1 to B5, wherein the first lead further includes:
a main surface (251) facing the first side of the thickness direction and being covered with the sealing resin;
a first end face (253) facing in a first direction (x) perpendicular to the thickness direction and being connected to the main surface and the second bottom surface; and
a second end face (254) facing in a second direction (y) perpendicular to the thickness direction and the first direction, the second end face being connected to the main surface and the second bottom surface,
wherein the first end face and the second end face are exposed from the sealing resin.

Clause B7. (FIG. 35) The semiconductor device according to any one of clauses B1 to B6, wherein the second back surface is formed with a plurality of first convexities (291) extending in a direction perpendicular to the thickness direction.

Clause B8. (FIG. 35) The semiconductor device according to any one of clauses B1 to B7, wherein the connection surface is formed with a plurality of second convexities (292) extending in the thickness direction.

Clause B9. The semiconductor device according to any one of clauses B1 to B8, wherein the first lead is not electrically connected to the semiconductor element.

Clause B10. The semiconductor device according to any one of clauses B1 to B8, wherein the first lead is electrically connected to the semiconductor element.

Clause B11. The semiconductor device according to any one of clauses B1 to B10, wherein the element main surface of the semiconductor element faces the second side of the thickness direction, and
the electrode is electrically connected to the conductive member.

Clause B12. (sixth embodiment, FIGS. 45-47) The semiconductor device according to any one of clauses B1 to B10, further comprising a connection member (5) electrically connecting the semiconductor element and the conductive member, wherein
the conductive member includes a die pad (27) on which the semiconductor element is mounted,
the element main surface of the semiconductor element faces the first side of the thickness direction, and
the connection member is electrically connected to the electrode and the conductive member.

Clause B13. The semiconductor device according to any one of clauses B1 to B8, wherein
the conductive member includes a second lead (21) spaced apart from the first lead,
the second lead includes a third bottom surface (212) facing the second side of the thickness direction, a fourth bottom surface (214) facing the second side of the thickness direction and disposed closer to the first side of the thickness direction than is the third bottom surface, and a second connection surface (215) connected to the third bottom surface and the fourth bottom surface,
the third bottom surface, the fourth bottom surface and the second connection surface are exposed from the sealing resin, and
the third bottom surface is flush with the resin bottom surface.

Clause B14. (FIGS. 36-39) A method for manufacturing a semiconductor device, the method comprising:
an element bonding process in which a semiconductor element is bonded to a lead frame main surface (81A) facing a first side of a thickness direction of a lead frame (81);
a resin forming process in which a sealing resin is formed in a manner covering a portion of the lead frame and the semiconductor element;
a groove forming process in which a groove (83) is formed such that the groove extends from a lead frame bottom surface (81B) facing a second side of the thickness direction of the lead frame and into an intermediate portion of the lead frame in the thickness direction; and
a cutting process in which a cut is made to a removal area extending along the groove and having a smaller width than the groove so that an entirety of the removal area overlaps with the groove as viewed in the thickness direction, the cut being performed such that entire portions of the lead frame and the sealing resin that correspond to the removal area are removed in the thickness direction,
wherein the groove includes:
a first groove (831) extending in a first direction perpendicular to the thickness direction;
a second groove (832) extending in a second direction perpendicular to the thickness direction and the first direction; and
a connection surface (833) disposed at a location where the first groove and the second groove intersect, the connection surface being connected to the first groove and the second groove and curved as viewed in the thickness direction.

Clause B15. The method according to clause B14, wherein the groove is formed by laser irradiation in the groove forming process.

1. A semiconductor device comprising:
a semiconductor element including an element main surface facing in a thickness direction and being provided with an electrode; and
a sealing resin including a resin top surface facing a first side of the thickness direction, the sealing resin covering the semiconductor element, wherein
the element main surface and the resin top surface are rectangular, and
a first edge of the element main surface is inclined with respect to a second edge of the resin top surface, as viewed in the thickness direction.

2. The semiconductor device according to claim 1, wherein an inclination angle of the first edge relative to the second edge is greater than 0° and less than 45° as viewed in the thickness direction.

3. The semiconductor device according to claim 2, wherein the inclination angle is not less than 5° and not greater than 45°.

4. The semiconductor device according to claim 3, wherein the inclination angle is 45°.

5. The semiconductor device according to claim 1, wherein the resin top surface has four corners including a first corner located closest to the first edge of the four corners, and
as viewed in the thickness direction, a distance between the first edge and the first corner is not less than 25% of a length of a diagonal of the resin top surface.

6. The semiconductor device according to claim 1, further comprising a conductive member electrically connected to the semiconductor element, wherein
the semiconductor element is disposed such that the element main surface faces a second side of the thickness direction, and
the electrode is electrically connected to the conductive member.

7. The semiconductor device according to claim 1, further comprising:
a conductive member electrically connected to the semiconductor element; and
a connection member electrically connecting the semiconductor element and the conductive member to each other, wherein
the semiconductor element is disposed such that the element main surface faces the first side of the thickness direction, and
the connection member is electrically connected to the electrode and the conductive member.

8. The semiconductor device according to claim 6, wherein the conductive member includes a plurality of leads each having a lead main surface facing the first side of the thickness direction and a lead back surface facing the second side of the thickness direction.

9. The semiconductor device according to claim 8, wherein the sealing resin includes a resin bottom surface facing the second side of the thickness direction, and
the lead back surfaces of the plurality of leads are exposed from the resin bottom surface.

10. The semiconductor device according to claim 9, wherein
the plurality of leads includes first leads and second leads,
the lead back surfaces of the first leads are arranged along a first direction parallel to the second edge,
the lead back surfaces of the second leads are spaced apart from the lead back surfaces of the first leads in a second direction perpendicular to the thickness direction and the first direction, while also being arranged along the first direction.

11. The semiconductor device according to claim 10, wherein the plurality of leads further include third leads, and
the lead back surfaces of the third leads are disposed along the second direction.

12. The semiconductor device according to claim 10, wherein the plurality of leads include a fourth lead, and
the fourth lead has a first end face facing in the first direction and exposed from the sealing resin, and a second end face facing in the second direction and exposed from the sealing resin, the fourth lead being not electrically connected to the semiconductor element.

13. The semiconductor device according to claim 10, wherein the plurality of leads include a fifth lead, and
the fifth lead has a third end face facing in the first direction and exposed from the sealing resin, and a fourth end face facing in the second direction and exposed from the sealing resin, the fifth lead being electrically connected to the semiconductor element.

14. The semiconductor device according to claim 8, wherein the plurality of leads includes a die pad on which the semiconductor element is mounted,
the die pad has a die pad main surface facing the first side of the thickness direction,
the die pad main surface is rectangular, and
as viewed in the thickness direction, the die pad main surface has a third edge is substantially parallel to the first edge.

15. The semiconductor device according to claim 8, wherein the plurality of leads include a die pad on which the semiconductor element is mounted,
the die pad has a die pad main surface facing the first side of the thickness direction,
the die pad main surface is rectangular, and
as viewed in the thickness direction, the die pad main surface has a third edge is substantially parallel to the second edge.

16. The semiconductor device according to claim 6, further comprising a base member having a base member main surface facing in the first side of the thickness direction and a base member back surface facing in the second side of the thickness direction,
wherein the conductive member includes a conductive part disposed in a through-hole extending through the base member in the thickness direction.
